(19) United States
(12) Patent Application Publication
(10) Pub. No.: US 2025/0098543 A1
(43) Pub. Date: Mar. 20, 2025

(54) FLEXIBLE TRANSDUCER

(71) Applicant: Purdue Research Foundation, West Lafayette, IN (US)

(72) Inventors: Robert A Nawrocki, Lafayette, IN (US); Jinsheng Fan, Minneapolis, MN (US)

(73) Assignee: Purdue Research Foundation, West Lafayette, IN (US)

(21) Appl. No.: 18/889,014

(22) Filed: Sep. 18, 2024

Related U.S. Application Data
(60) Provisional application No. 63/539,077, filed on Sep. 18, 2023.
(60) Provisional application No. 63/539,081, filed on Sep. 18, 2023.

(51) Int. Cl. H10N 30/88; H10N 30/00; H10N 30/87

(52) U.S. Cl. CPC H10N 30/88; H10N 30/101; H10N 30/87

(57) ABSTRACT

A stretchable transducer includes one or more rectangular sensing regions, each including one or more sensing layers, each including fibrous sensing materials sandwiched between a top and a bottom electrode, two or more substrates adapted to sandwich the one or more sensing layers further forming one or more serpentine regions adapted to allow stretchability of the stretchable transducer, the two or more substrates having axial gaps therebetween, one or more electrical connection regions distally extended longitudinally from the one or more serpentine regions, wherein the one or more electrodes extend longitudinally from the one or more sensing regions through the gaps formed in the serpentine regions and terminating at the one or more electrical connection regions, two clamping regions distally extended longitudinally from the one or more electrical connection regions adapted to provide coupling to the stretchable transducer, and an encasing layer.

### CROSS-REFERENCE TO RELATED APPLICATIONS

The present non-provisional patent application is related to and claims the priority benefit of U.S. Provisional Patent Application Ser. 63/539,077, filed Sep. 18, 2023, and further is related to and claims the priority benefit of U.S. Provisional Patent Application Ser. 63/539,081, filed Sep. 18, 2023, the contents of each of which are hereby incorporated by reference in its entirety into the present disclosure.

### STATEMENT REGARDING GOVERNMENT FUNDING

None.

### TECHNICAL FIELD

The present disclosure generally relates to transducers and in particular to flexible transducers.

### BACKGROUND

This section introduces aspects that may help facilitate a better understanding of the disclosure. Accordingly, these statements are to be read in this light and are not to be understood as admissions about what is or is not prior art.

Electrospinning technique is an economical, and versatile process to directly produce piezoelectrically active Polyvinylidene fluoride or polyvinylidene difluoride (PVdF) nano/microfibers to build force/pressure sensors with features of flexibility, biocompatibility, and cost benefit. Many researchers have studied the electrospinning PVdF nano/microfibers for varying applications and reported the macromolecular orientation, crystalline structures, and the effect of additives in PVdF electrospinning nano/microfibers. In 2011, scientists pioneered a modified electrospinning technique for the direct fabrication of high-efficiency piezoelectric membranes. The research process employed a consistent, parallel electric field that, in combination with high electric field strength and stretch ratio. The electric field can orient PVdF molecular chains and improve a polymorphic transition from α-phase to β-phase. In a 2015 study, researchers discussed the creation of highly extensible piezoelectric structures made of electrospinning PVdF-based nanofibers. These structures were produced by twisting electrospinning ribbons. The study revealed that the twisting procedure enhanced not only the failure strain but also the overall strength and durability. The manufactured yarns and coils demonstrated significant potential for use in high-performance, lightweight materials and super-elastic piezoelectric devices, and as part of flexible energy harvesting applications.

The alignment of electrospinning nano/microfibers has emerged as a significant field of research due to the superiority of aligned fibers over randomly oriented fibers. In the case of processing conditions, the alignment of electrospinning nanofibers, achieved through the use of a rotating collector, can enhance the generation of the β-phase within the fibrous architecture. The rotating collector in the electrospinning setup has a feature of relative movement between the fiber generator and the collector, which is referred to as a dynamic collection electrospinning. However, constructing a dynamic collection electrospinning setup is complex. Another type of electrospinning setup known as a static collection electrospinning setup, where the fiber generator and collector remain relatively static during the electrospinning process, is simpler to build.

Among many static collection electrospinning methods, gap electrospinning is a relatively new technique to produce aligned nano/microfibers. Applying the gap electrospinning technique can effectively produce length-controllable aligned fibers in a wide range from a few centimeters to even one meter long, according to the prior art. The core component of a gap electrospinning setup includes an electrically positively connected needle and a pair of parallel plates that are electrically negatively connected. The electrospinning process is governed by the electrical forces acting on free charges present on the surface or within a polymer solution. Typically, these free charges are ions that move under the influence of the electric field, rapidly transferring force to the solution. Initially, the solution's surface near the needle's open tip is almost flat. However, when a high voltage is applied to the solution within the needle, the surface assumes an approximate spherical section shape due to the interplay of electrical forces and surface tension, given that the base is retained as a circle by the pipette's lip. As the voltage potential escalates, a solution jet is drawn from the tip, triggering the onset of electrospinning. During the gap electrospinning process, the jet whipping effect plays a crucial role in continuously driving the solution jet to span across the gap between static collector plates. The electric field around the collector plates can effectively attract the positively charged microfibers to align the microfibers in parallel with the electric field direction. Due to the instability of the polymer solution jet, namely the whipping effect, the jet can move back and forth over a wide gap (e.g., 10 cm as the gap width) to form centimeter-long aligned nano/microfibers.

Advantages of aligned fibers include improved mechanical properties, accelerated charge transport, and a more uniform spatial structure. Aligned electrospinning nano/microfiber membranes have anisotropic mechanical properties. Researchers have successfully produced type I collagen electrospinning membranes, demonstrating that the mechanical properties were affected by the membrane's fiber alignment structure. Through tensile testing, researchers found a peak stress of 1.5±0.2 MPa along the fiber alignments, and 0.7±0.1 MPa in the cross-fiber direction. Further, by increasing the drum surface speed to 17.2 m/s, researchers have generated highly aligned poly(butylene terephthalate) electrospinning fiber membranes. These membranes exhibited a tensile strength of about 20 MPa along the fiber alignment, with a markedly lower strength of 1 MPa in the cross-fiber direction. Young's modulus is a measure of the ability of a material to withstand changes in length when under lengthwise tension or compression, which is meaningful only in the range in which the stress is proportional to the strain, and the material can return to the original dimensions when the external force is removed. Young's modulus describes the elastic properties (e.g., stretchability) of a solid undergoing tension or compression in only one direction. Young's modulus lower than 103 MPa are classified as soft materials. Young's modulus of aligned microfiber-based membrane is anisotropic and Young's modulus of conventional electrospinning microfiber-based membrane is isotropic. By selecting a stretching direction with a lower Young's modulus in the device design, the aligned electrospinning nano/microfiber based devices are more stretchable compared with conventional electrospinning microfiber based devices.

Researchers have observed an anisotropically aligned pattern of nanofibrous structures, achieved by electrospinning microfibers on a spring-like template. A portion of the nanofibers were loosely suspended and aligned along the longitudinal direction of the spring-like template. Researchers investigated the tensile strengths and elastic moduli of aligned electrospinning microfiber membrane and compared the results with measurements taken from randomly distributed electrospinning microfiber membranes. The mechanical property tests revealed that the randomly dispersed microfiber membranes showed mechanical isotropy, with near-identical tensile strength and elasticity in both directions, due mainly to the random distribution of microfibers across each direction. However, the aligned electrospinning microfiber membranes exhibited significantly higher tensile strengths and elasticities in the nanofiber alignment direction. This was a result of the well-aligned nanofibers along the direction of tensile load. Conversely, lower tensile strength and elasticity were measured in the direction perpendicular to the fiber alignment direction, a phenomenon ascribed to the weak connection between neighboring parallel fibers. Aligned piezoelectric PVdF microfibers produced by gap electrospinning were useful to build stretchable piezoelectric force/pressure sensors. The gap electrospinning technique has been proven to provide new insight into the nature of electrospinning technology, which can greatly expand the versatility of electrospinning technology to create devices for a wide range of applications.

Another part of the research work in this study was about adding three-dimensionality to two-dimensional (2D) electrospinning PVdF microfibers through the integration of three-dimensional (3D) printed architectures with electrospinning PVdF microfibers. Electrospinning PVdF microfibers are often limited within flat or fiber-like geometries which are regarded as 2D structures. The idea of adding three-dimensionality to electrospinning nano/microfibers is not just simply expanding the structure of PVdF microfibers from 2D to 3D. The integration process is provided to add more functionality to the previously fabricated electrospinning PVdF microfiber-based sensors, such as stretchability. Researchers combined two advanced technologies: electrospinning and 3D printing for an innovative and straightforward approach to creating shape-changing hydrogels, which exhibited rapid transformation and augmented design capabilities in three dimensions. Complex patterns were produced on mesostructured, stimuli-responsive electrospinning membranes, thus adjusting internal stresses both within the plane and between layers that originate from inconsistencies in swelling or shrinkage. A range of swiftly transforming hydrogel actuators was developed with unique responsive actions such as reversible and irreversible creation of 3D structures, 3D tube folding, and establishment of 3D forms with multiple low-energy states. Another team of researchers has reported the integration of near-field electrospinning PVdF nano/microfibers with a 3D printed wavy substrate, implemented through a combination of direct-write and in-situ poled processes. The fabricated devices were named the wavy-substrate self-powered sensors. The production procedures involved additive manufacturing of a flexible and sinusoidally waved substrate, followed by metallization and near-field electrospinning of fibers onto the 3D topography. The 3D architecture significantly boosted the piezoelectric yield. As a final step, the piezoelectrically infused 3D structure was utilized in self-powered sensors for applications such as foot pressure detection, human motion tracking, and power generation induced by finger movements. The merged manufacturing technique proves existing electrospinning technologies can be evolved to build 3D structures and opens numerous potential applications in biomedical and wearable electronics.

However, a true stretchable transducer that can conform to myriad shapes is still needed. A stretchable transducer is needed that can adjust its shape in a variety of ways without losing its ability to provide high-sensitivity output.

Therefore, there is an unmet need for a novel stretchable transducer with high sensitivity that can adjust to myriad shapes.

### SUMMARY

A stretchable transducer is disclosed. The stretchable transducer includes one or more rectangular sensing regions. Each of the sensing regions includes one or more sensing layers. Each of the sensing layers includes fibrous sensing materials. The fibrous materials are sandwiched between a top and a bottom electrode. The sensing layers further include two or more substrates adapted to sandwich the one or more sensing layers within said one or more sensing regions. The two or more substrates form one or more serpentine regions adapted to allow stretchability of the stretchable transducer, wherein the two or more substrates extend longitudinally in between the one or more sensing regions and outward from the one or more sensing regions thus forming the one or more serpentine regions and further outward to one or more electrical connection regions and yet further outward to two clamping regions, the two or more substrates having axial gaps therebetween, thus forming the one or more serpentine regions and thus allowing insertion of the one or more sensing regions in said gaps. The one or more electrical connection regions distally extended longitudinally from the one or more serpentine regions, wherein the one or more electrodes extend longitudinally from the one or more sensing regions through said gaps formed in said serpentine regions and terminating at said one or more electrical connection regions. The two clamping regions distally extended longitudinally from the one or more electrical connection regions adapted to provide coupling to the stretchable transducer. The stretchable transducer further includes an encasing layer adapted to encase said one or more sensing regions, said one or more sensing regions, said one or more electrical connection regions, and said two clamping regions.

A stretchable transducing system is also disclosed. The stretchable transducing system includes a stretchable transducer, and an electrical circuit configured to i) receive an electrical signal from the stretchable transducer in a sensing mode corresponding to changes in environment, or ii) provide an electrical signal to the stretchable transducer in an actuator mode to thereby cause changes in the environment. The stretchable transducer includes one or more rectangular sensing regions. Each of the sensing regions includes one or more sensing layers. Each of the sensing layers includes fibrous sensing materials. The fibrous materials are sandwiched between a top and a bottom electrode. The sensing layers further include two or more substrates adapted to sandwich the one or more sensing layers within said one or more sensing regions. The two or more substrates form one or more serpentine regions adapted to allow stretchability of the stretchable transducer, wherein the two or more substrates extend longitudinally in between the one or more sensing regions and outward from the one or more sensing regions thus forming the one or more serpentine regions and further outward to one or more electrical connection regions and yet further outward to two clamping regions, the two or more substrates having axial gaps therebetween, thus forming the one or more serpentine regions and thus allowing insertion of the one or more sensing regions in said gaps. The one or more electrical connection regions distally extended longitudinally from the one or more serpentine regions, wherein the one or more electrodes extend longitudinally from the one or more sensing regions through said gaps formed in said serpentine regions and terminating at said one or more electrical connection regions. The two clamping regions distally extended longitudinally from the one or more electrical connection regions adapted to provide coupling to the stretchable transducer. The stretchable transducer further includes an encasing layer adapted to encase said one or more sensing regions, said one or more sensing regions, said one or more electrical connection regions, and said two clamping regions.

### BRIEF DESCRIPTION OF FIGURES

FIGS. 1a, 1b, and 1c are schematics of a stretchable transducer, according to the present disclosure.

FIG. 1d is a schematic of polymer chain conformation of β-phase Polyvinylidene fluoride or polyvinylidene difluoride (PVdF) with a dipole.

FIG. 2 is a schematic of a gap electrospinning setup, according to the present disclosure.

FIG. 3 is a graph of Young's modules in MPa vs. thermoplastic polyurethane (TPU) concentration in Wt. %.

FIG. 4 is a graph of Young's modulus in MPa vs. angle of alignment.

FIG. 5 is a graph of Young's modulus in MPa vs. PVdF and TPU microfibers at different fiber alignment directions.

FIG. 6 is a graph of piezoelectric output in pC/N vs. TPU concentration in Wt. %.

FIG. 7 is a schematic pf fabrication process for the stretchable electrospinning PVdF-TPU microfiber-based transducer of the present disclosure, including a fused deposition modeling (FDM) 3D printing of the top, middle, and bottom substrates, respectively (see FIG. 1b).

FIGS. 8a, 9a, 10a, 10c, 10e, 11a, 11c, and 11e are schematics of eight different transducer embodiments, according to the present disclosure.

FIGS. 8b, 9b, 10b, 10d, 10f, 11b, 11d, and 11f are graphs of transducer outputs (e.g., graphs of piezoelectric outputs in V vs. time in seconds in response to changes in the environment) for the eight embodiments shown in FIGS. 8a, 9a, 10a, 10c, 10e, 11a, 11c, and 11e, respectively.

FIG. 12 is a schematic of the first embodiment of the transducers of the present disclosure with one PVdF-electrode assembly made from the gap electrospinning process and DIW deposition of electrodes, and two (top and bottom) substrates made from FDM 3D printing having varying thicknesses of the bottom substrate and the corresponding transducer outputs.

FIG. 13 is a schematic of the first embodiment of the transducers of the present disclosure with one PVdF-electrode assembly made from the gap electrospinning process and DIW deposition of electrodes, and two (top and bottom) substrates made from FDM 3D printing having varying thicknesses of the top substrate and the corresponding transducer outputs.

FIG. 14 is a schematic of the third embodiment of the transducers of the present disclosure with two PVdF-electrode assemblies made from the gap electrospinning process and DIW deposition of electrodes, and three (top, middle, and bottom) substrates made from FDM 3D printing having varying thicknesses of the top substrate and the corresponding transducer outputs.

FIG. 15 is a schematic of the third embodiment of the transducers of the present disclosure with two PVdF-electrode assemblies made from the gap electrospinning process and DIW deposition of electrodes, and three (top, middle, and bottom) substrates made from FDM 3D printing having varying thicknesses of the middle substrate and the corresponding transducer outputs.

FIG. 16 is a schematic of the third embodiment of the transducers of the present disclosure with two PVdF-electrode assemblies made from the gap electrospinning process and

DIW deposition of electrodes, and three (top, middle, and bottom) substrates made from FDM 3D printing having varying thicknesses of the bottom substrate and the corresponding transducer outputs.

FIG. 17 is a schematic of the sixth embodiment of the transducers of the present disclosure with two PVdF-electrode assemblies made from the gap electrospinning process and DIW deposition of electrodes, and three (top, middle, and bottom) substrates made from FDM 3D printing having varying thicknesses of the top substrate and the corresponding transducer outputs.

FIG. 18 is a schematic of the sixth embodiment of the transducers of the present disclosure with two PVdF-electrode assemblies made from the gap electrospinning process and DIW deposition of electrodes, and three (top, middle, and bottom) substrates made from FDM 3D printing having varying thicknesses of the middle substrate and the corresponding transducer outputs.

FIG. 19 is a schematic of the sixth embodiment of the transducers of the present disclosure with two PVdF-electrode assemblies made from the gap electrospinning process and DIW deposition of electrodes, and three (top, middle, and bottom) substrates made from FDM 3D printing having varying thicknesses of the bottom substrate and the corresponding transducer outputs.

FIGS. 20a, 20b, and 20c are schematics of the transducer of the present disclosure according to one embodiment with varying middle substrate thicknesses (see FIG. 1b).

FIGS. 21a, 21b, and 21c are graphs of capacitance in pF vs. weight in g of the transducer for the variations shown in FIGS. 20a, 20b, and 20c, accordingly, with the transducer is subjected to different stretching ratios (i.e., 10%, 20%, and 30%).

FIGS. 22a, 22b, 22c are graphs of the piezo output in V vs. time in seconds results for middle layer substrate thickness shown in FIG. 1b of 0.6 mm, 1.2 mm, and 2.0 mm, respectively.

FIGS. 22d, 22e, and 22f are the piezo output in V vs. force in N for middle layer substrate thickness shown in FIG. 1b of 0.6 mm, 1.2 mm, and 2.0 mm, respectively.

FIGS. 23a, 23b, and 23c are schematics of one embodiment of a transducer according to the present disclosure showing three different angles of the serpentine areas.

FIGS. 24a, 24b, and 24c are graphs of capacitance vs. weight of the transducer for the three angles shown in FIGS. 23a, 23b, and 23c, respectively.

FIGS. 25a, 25b, and 25c are graphs of the piezo output in V vs. time in seconds for the three angles results are shown in shown in FIGS. 23a, 23b, and 23c, respectively.

FIGS. 25d, 25e, and 25f are graphs of piezo output in V vs. force in N for the three angles results are shown in shown in FIGS. 23a, 23b, and 23c, respectively.

FIG. 26a is a photograph of the electrospinning piezoelectrically active PVdF-TPU microfiber membrane with DIW printed electrodes' patterns in a state of stretch.

FIG. 26b is a photograph of the transducers in a state of no stretch.

FIG. 26c is a top view of a 2×4 capacitive sensing matrix made from the transducers of the present disclosure.

FIG. 26d provides variations in the capacitance of the 2×4 capacitive sensing matrix of FIG. 26c subjected to applied forces.

FIG. 26e is a top view of a 4×4 capacitive sensing matrix made from the transducers of the present disclosure.

FIG. 26f provides variations in the capacitance of a 4×4 capacitive sensing matrix of FIG. 26e subjected to applied forces.

FIGS. 27a, 27b, and 27c are photographs of a testing rig for testing stretchable 2×2 piezoelectric pressure sensing matrix fixed on a fully FDM 3D printed biaxial linear stretcher (FIG. 27a), where the fabricated 2×2 sensing matrix was integrated with light emitting diodes (LEDs) to visualize the piezoelectric output signals generated by sensors in the matrix; wherein FIG. 27b shows the LEDs when applying force; and FIG. 27c shows LEDs when releasing force.

FIG. 28a is a photograph of a soft gripper operated by air with integrated stretchable transducers of the present disclosure.

FIG. 28b is a graph of pressure in pounds per square inches vs. time while also showing the piezoelectric output in V for the soft gripper of FIG. 28a in operation.

### DETAILED DESCRIPTION

For the purposes of promoting an understanding of the principles of the present disclosure, reference will now be made to the embodiments illustrated in the drawings, and specific language will be used to describe the same. It will nevertheless be understood that no limitation of the scope of this disclosure is thereby intended.

In the present disclosure, the term “about” can allow for a degree of variability in a value or range, for example, within 10%, within 5%, or within 1% of a stated value or of a stated limit of a range.

In the present disclosure, the term “substantially” can allow for a degree of variability in a value or range, for example, within 90%, within 95%, or within 99% of a stated value or of a stated limit of a range.

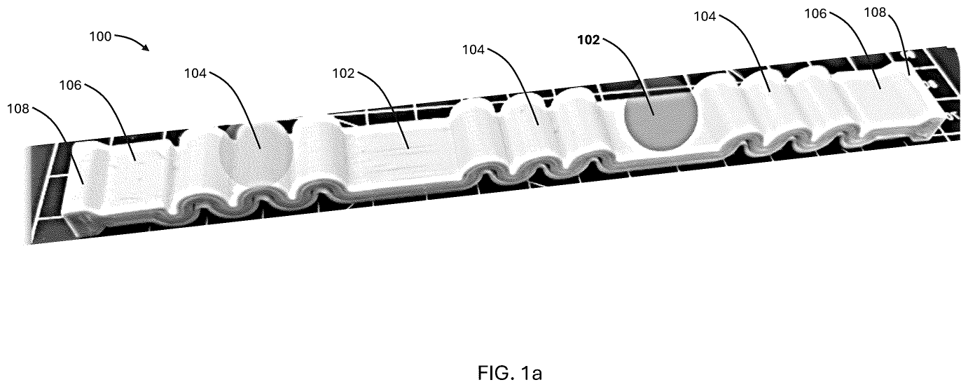

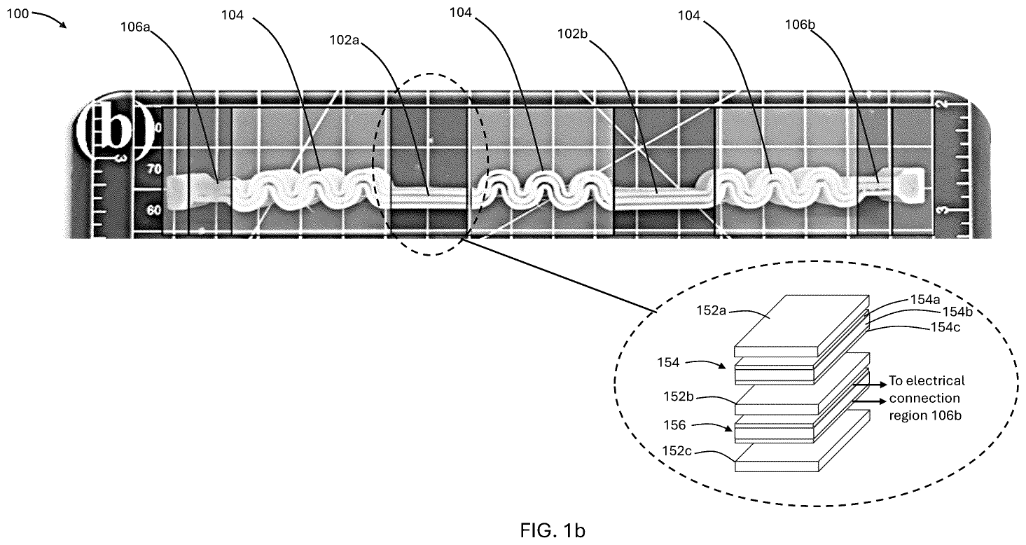

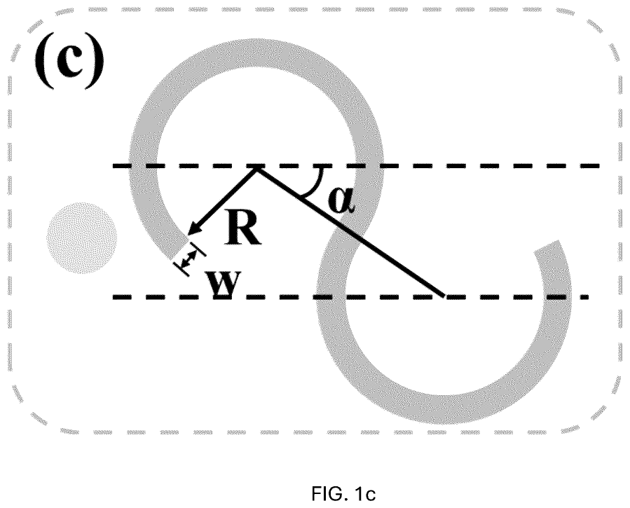

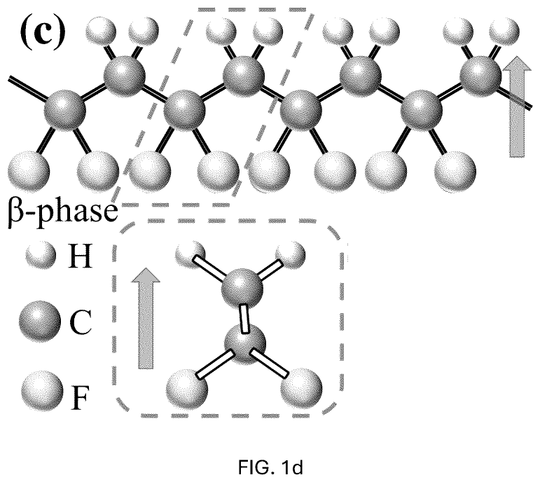

A novel stretchable transducer is presented herein with high sensitivity that can adjust to myriad shapes. Towards this end, a fused deposition modeling (FDM) 3D printed flexible serpentine structure was integrated with gap electrospinning aligned Polyvinylidene fluoride or polyvinylidene difluoride (PVdF)-based microfibers to build a transducer, e.g., a piezoelectric force/pressure sensor. Referring to FIGS. 1a-1c, schematics of the stretchable transducer 100, according to the present disclosure is provided. Specifically, FIG. 1a is a schematic of a stretchable transducer 100, according to the present disclosure. The transducer 100 includes one or more flat activation regions 102 adjacent one or more serpentine regions 104. The flat activation regions 102 are adapted to sense changes in the environment in a sensor mode whereby an electrical signal is generated commensurate with the change in the environment; or be activated by application of an electrical signal in an activation mode to cause a change in the environment commensurate with the electrical signal. The one or more serpentine regions 104 are adapted to provide stretchability and conformance to a various shapes. Shown in FIG. 1a, is a transducer with two flat activation regions 102 and three serpentine regions 104, however, the transducer of the present disclosure can have more or less numbers of flat activation regions 102 adjacent to serpentine regions 104. For example, according to one embodiment, the transducer may have one single flat activation region 102 that is adjacent one or two serpentine regions 104. The number of flat activation regions 102 adjacent serpentine regions 104 is dependent on the application of the transducer, i.e., the need for multiple measurements, the need for a known amount of stretch, etc.

The transducer 100 also includes electrical connection regions 106 and clamping regions 108. The electrical connection regions 106 are intended to make electrical connections to the flat activation regions 102, i.e., one electrical connection region 106 to one flat activation region 102. The clamping regions 108 are adapted to provide a mounting mechanism for the transducer 100 to an object (not shown).

Referring to FIG. 1b, a side-view schematic of the transducer 100 is shown. In the side-view of FIG. 1b, two flat activation regions 102a and 102b are shown, one in an exploded view in a side panel, described further below. The side panel shows a sandwich structure, according to one embodiment of the transducer of the present disclosure, having a top, middle, and bottom substrates 152a, 152b, and 152c, respectively, e.g., made from thermoplastic polyurethane (TPU) and formed by FDM, along with two PVdF-electrode subassemblies 154 and 156, wherein each PVdF-electrode subassembly (e.g., 154) includes a PVdF-TPU microstructure 154b formed using an electrospinning process, with accompanying electrodes 154a and 154c, e.g., silver electrodes, that are deposited on top and bottom surfaces of the PVdF-TPU microstructure 154b with direct ink writing (DIW). As shown in the side panel of FIG. 1b, there may be two such PVdF-electrode subassemblies (154 and 156) or more or less each with electrode connectivity spanning to the electrical connection regions 106a and 106b. That is the two electrodes 154a and 154c of the PVdF-electrode subassembly 154, terminate at the electrical connection region 106a, while the electrodes of the PVdF-electrode subassembly 156 terminate at the electrical connection region 106b, as shown. The connectivity between electrodes 154a and 154c and the electrodes of the PVdF-electrode subassembly 156 is discussed further below. However, it should be understood that the transducer 100 may include only one PVdF-electrode subassembly (e.g., 154) thus eliminating the need for the middle substrate 152b, and the PVdF-electrode subassembly 156. It should be noted that the two electrodes 154a and 154c of the PVdF-electrode subassembly 154 and similarly the two electrodes of the PVdF-electrode subassembly 156 extend to the electrical connection regions 106a and 106b, respectively. That is, as an example, the electrodes 154a and 154c each has a rectangular shape matching the rectangular shape of the PVdF-TPU microstructure 154b, with an elongated segment (not shown) extending to the electrical connection regions 106a. The entirety of the PVdF-electrode subassemblies 154 and 156 with the associated elongated segments (not shown) are placed in the gaps formed between the top, middle, and bottom substrates 152a, 152b, and 152c. As discussed above, the top, middle, and bottom substrates 152a, 152b, and 152c are formed using FDM, while the PVdF-electrode subassemblies 154 and 156 are based on gap electrospinning and DIW processes.

FIG. 1c is a schematic showing the angle (defined in the figure) for the serpentine regions 104. FIG. 1c is schematic of a polymer chain conformation of β-phase PVdF.

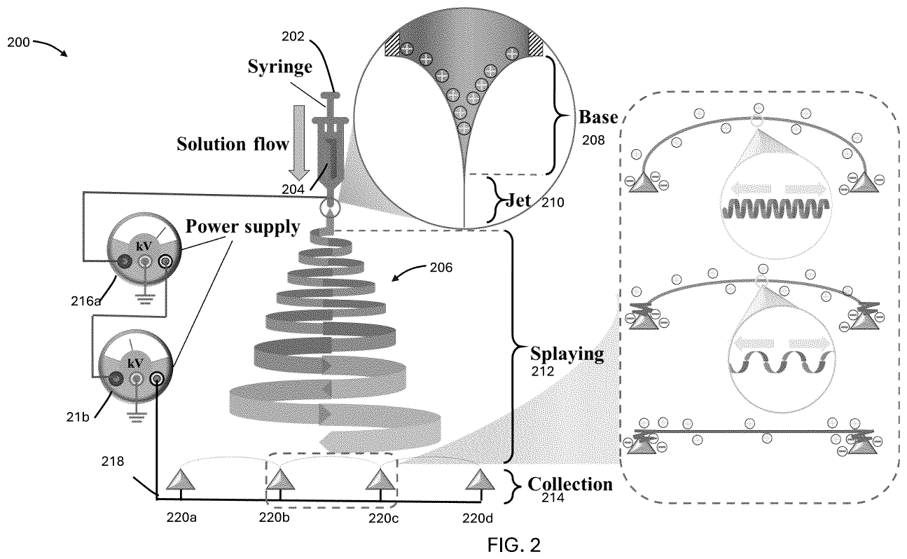

A gap electrospinning technique, known to a person having ordinary skill in the art, was applied to effectively produce well-aligned length-controllable PVdF microfibers. Referring to FIG. 2, a schematic of a custom-made gap electrospinning process 200 is shown adapted to produce aligned microfibers. The gap electrospinning process 200 includes a deposition syringe 202 (or any other injectable vessel) which uses a source of force to eject a polymer solution 204 out of the syringe 202. The force results in an electrospinning jet 206. A stable electrospinning jet 206 includes four regions: a base region 208, a jet region 210, a splaying region, 212 and a collection region 214. The electrospinning process takes place when electrical forces generated from a power supply 216a surpass the surface tension at the surface of a polymer solution 204, triggering the expulsion of an electrically charged stream. Once the stream undergoes drying or solidification due to solvent evaporation, the stream leaves behind an electrically charged thread. The charged thread is controlled and sped up by electrical forces, allowing the deposition of the charged thread on collectors 218 that could take the form of sheets or other geometric shapes. The stable electrospinning jet 206 originates from the electrically charged area at the base region 208, traverses through the jet region 210, splits into numerous strands in the splaying region 212, and concludes in the collection region 214. Positive high voltage potentials which were in the range of 15 kV to 25 kV were applied to the needle through the direct current (DC) power supply 216a (Gamma High Voltage). Negative high voltage potentials which were in the range of −3 kV to −1 kV were applied through another DC power supply 216b to electrically connected but spatially separated parallel aluminum plates (20 cm in length, 20 cm in width, and 0.5 mm in thickness) used as the collector. The applied negative voltage was determined by the results from literature reviewed. In a study examining the impact of varying electrical potentials applied to a pair of steel blades serving as collectors on the effectiveness of electrospinning, some interesting results were discovered. When a negative voltage was applied to the steel blades, a larger number of fibers were attracted, with fibers aligned and collected from the tip of one blade to the other. However, when the negative voltage applied to the steel blades was raised to above −4 kV, no fibers deposited on the blades, as the electrospinning jet was repelled. This phenomenon is because the ionization of the air at such a high voltage at the edge of the blade. The negatively charged ions would gravitate towards the positively charged electrospinning jet, leading to the jet possibly acquiring a net negative charge. Consequently, a repulsive force would develop between the negatively charged steel blades and the increasingly negatively charged electrospinning jet. This would result in the deflection of the electrospinning jet from the steel blades prior to the deposition of fibers on the collectors. Another collection system, made up of an insulating hollow cylinder and grating-like electrodes, has been demonstrated to produce highly oriented electrospinning fibers. The hollow cylinder-shape collector with a negative connection were more successful and efficient in drawing fibers to stretch across the gap. The applied negative voltage potential on the collector allowed the whipping jet to be effectively constrained within the cylindrical collector and spread to align across the electrode gaps. As the fibers carried residual positive charges, the fiber alignment would be further enhanced, as these charges would continue to pull the fibers towards the closest electrodes 220a, 220b, 220c, and 220d, until these fibers were fully extended, unless the fiber's repelling forces exceeded the forces pulling them to align across the electrode gaps.

During the process of gap electrospinning, a 5 ml syringe 202 installed with a 21-gauge needle loaded with a solution 204 with a suitable PVdF concentration was utilized. The gap electrospinning process 200 was constructed with the positively connected needle and two negatively charged plates as the collector 218, which were in parallel with each other. The flying PVdF microfibers were mainly collected between the front gap area towards the needle. The length of aligned PVdF microfibers was in a range from 1 cm to 10 cm, which was mainly controlled by the structure of the gap electrodes 220a, 220b, 220c, and 220d. The well-aligned PVdF microfibers were measured to find the anisotropic nature of mechanical properties. The Young's modulus measured by applying a tensile load perpendicular to the microfiber length direction is much lower than that measured by adding a tensile load in parallel with the microfiber length direction. The stretching direction with the lowest Young's modulus is considered the proper direction selected from the aligned microfibers to build stretchable devices. The surface metallization of electrospinning PVdF microfibers was implemented through direct ink writing (DIW) to print stretchable silver conductor ink on the surface of PVdF microfiber membranes to obtain designed electrode patterns. A fused deposition modeling (FDM) 3D printer was used to print soft serpentine structures, which is capable of greatly enhancing the transducer's output and directly enabling the transducer to be stretchable with hybrid sensing mechanisms including piezoelectric and capacitive pressure sensing mechanisms. The stretchable PVdF-based transducer of the present disclosure is adapted to also be built as a stretchable transducer matrix and be integrated with a soft gripper. PVdF pellets (Mw=180,000, 275,000, and 534,000), acetone, and N, N-dimethylformamide (DMF) were purchased from Sigma-Aldrich Inc., USA. PVdF pellets (Mw=395,000, and 480,000) were received from Kynar® PVdF company. The typical procedures to prepare the solution for electrospinning are described as follows in detail. The DMF and acetone were mixed following a DMF:acetone volume ratio of 4:6, as a solvent mixture. PVdF pellets were dissolved into the DMF/acetone solvent mixture to prepare a 15 wt. % PVdF solution, and the mixture was magnetically stirred at 67° C. for 3 h to obtain a transparent solution.

Transparent 60 A TPU filament purchased from CoexFlex™ were dissolved into the solvent mixture used for electrospinning PVdF-TPU microfibers. A comparative study of the effect of TPU concentration on the piezoelectric and mechanical properties of PVdF microfibers has been performed with six different weight ratios of PVdF-TPU mixture solution. To prepare the solution for electrospinning PVdF-TPU microfibers, PVdF pellets and TPU materials were weighted and dissolved into the DMF/acetone solvent mixture. The total weight of polymeric materials dissolved into the solvent mixture was kept constant at 1500 mg regardless of the weight ratios of PVdF-TPU. The six different weight ratios of PVdF-TPU were 1500:0, 1350:150, 1200:300, 1050:450, 900:600, and 750:750 corresponding to six different TPU weight percentage values of 0 wt. %, 10 wt. %, 20 wt. %, 30 wt. %, 40 wt. %, and 50 wt. % in the total weight of polymeric materials (1500 mg). PVdF-TPU materials were dissolved into the DMF/acetone solvent mixture to prepare a 15 wt. % solution, and the mixture was magnetically stirred at 67° C. for 3 h to obtain a transparent solution. All materials were used as received without further modification.

The distance between the electrodes 220a, 220b, 220c, and 220d were adjusted from 1 cm to 10 cm and placed horizontally for gap electrospinning (FIG. 2) to find out the maximum length of microfiber bundle that can be produced and collected. The electrospinning solution was loaded in a 5 mL plastic syringe capped with a 21-gauge steel needle (inner diameter 0.8 mm) for electrospinning. The working distance (i.e., the distance between the needle tip and the geometry center of the front side of the gap between two electrodes 220a, 220b, 220c, and 220d) was 20 cm. During the electrospinning process, the solution flow rate was controlled by a syringe pump (KD Scientific) at 0.51 mL/h, and the voltages potentials applied on the needle tip (V+) and plate collector (V−) were adjusted accordingly. All experiments were performed under an air atmosphere with relative humidity in the range of 55% and 60%, which was measured by a digital humidity gauge (ThermoPro TP50).

Flexible 3D printable filaments were made of thermoplastic elastomers (TPE) mixed with soft rubber materials. The addition of soft rubber materials can adjust the mechanical properties (e.g., Young's modulus) of the composite filament which enables the filament to be more stretchable. TPU is one of the commonly used materials to make soft filaments for 3D printing purposes due to its advantages including abrasion resistance, flexibility, and oil-resistant properties. For the purposes of the present disclosure, a commercially available “X60 Ultra Flexible Filament” was used to print soft stretchable 3D architectures. The X60 ultra-flexible filament with a Shore hardness of 60 A is currently the softest and most flexible elastic filament available on the market. The flexible filament is widely used to print structures with flexibility and stretchability that can fulfill the requirements in soft robots related applications. However, the soft filament is very hard to print. A modified FDM 3D printer was used specifically to print the ultra-softest filament.

A LulzBot Taz 6 FDM 3D printer was modified to print soft 3D architectures using the above mentioned TPU filament. A commercially available printing head which is especially designed to print flexible materials was installed to print flexible filament smoothly to obtain high quality printing parts. The extruder designed to print flexible filament is named “Flexion extruder” by the manufacturer. The Flexion extruder facilitates rapid printing with flexible TPU filaments and enhances precision when using PLA filament. The precision machined components allow the modified 3D printer to apply increased pressure on the flexible TPU filament, achieve a high-pressure environment in the nozzle, and control feed speeds with great accuracy. Instead of the conventional spring, the Flexion Extruder employs a highly-stiffness lever to compress the flexible filament. This compression is adjusted by a cam and adjustment screw, offering higher tension and more precise control of the tension depending on the hardness of the filament being printed. In this study, all soft 3D architectures were printed by using the modified LulzBot Taz 6 3D printer and X60 ultra flexible filament following the same printing parameters. The typical printing parameters include infill density 90%, layer height 0.15 mm, build plate temperature 60° C., nozzle temperature 205° C., and printing speed 10 mm/s.

The mechanical properties of electrospinning microfibers were tested on an ADMET eXpert 2600 series of dual column electromechanical universal testing systems with a crosshead speed of 12 mm/min at room temperature (25° C.). Up to six specimens for each group were tested. The thickness of the microfibers was measured using a micrometer. Samples including electrospinning pure PVdF microfibers with different molecular weights and electrospinning PVdF-TPU microfibers with different TPU concentrations were listed in Table 1.

TABLE 1
Electrospinning PVdF microfibers and PVdF-TPU
microfibers for mechanical property test

| | | PVdF | | |
|---|---|---|---|---|
| | The molecular weight of | concentration | TPU concentration | Fiber |
| Group # | PVdF [g/mol] | [wt. %] | [wt. %] | direction |
| 1 | 180,000 | 100 | 0 | Random |
| 2 | 275,000 | 100 | 0 | Random |
| 3 | 395,000 | 100 | 0 | Random |
| 4 | 480,000 | 100 | 0 | Random |
| 5 | 534,000 | 100 | 0 | Random |
| 6 | 395,000 | 100 | 0 | 0° |
| 7 | 395,000 | 100 | 0 | 45° |
| 8 | 395,000 | 100 | 0 | 90° |
| 9 | 395,000 | 100 | 0 | Random |
| 10 | 395,000 | 90 | 10 | Random |
| 11 | 395,000 | 80 | 20 | Random |
| 12 | 395,000 | 70 | 30 | Random |
| 13 | 395,000 | 60 | 40 | Random |
| 14 | 395,000 | 50 | 50 | Random |
| 15 | 395,000 | 50 | 50 | 0° |
| 16 | 395,000 | 50 | 50 | 45° |
| 17 | 395,000 | 50 | 50 | 90° |

The manufactured transducer output was characterized by a custom-made system that would apply known forces and a customized charge amplifier circuit. The test procedures are described as follows. First, the sample was clamped and fixed on a linear stretcher, which was used to apply the stretching load manually. A series of known compression forces were applied at a frequency of 0.5 Hz to investigate the relationship between applied forces and transducer outputs. The performance of the stretchable transducer was determined by measuring the transducer output by applying a series of known forces when the transducer was stretched to different stretching ratios. A series of curves (i.e., calibration curves) which were amplitudes of transducer output voltages as a function of magnitudes of applied forces measured under different stretching ratios (i.e., 0%, 10%, 20%, and 30%) were plotted and analyzed to evaluate the performance of the stretchable transducer. Ideally, the calibration curves of a stretching-insensitive transducer should be the same regardless of the stretching ratios. A stretching insensitive pressure sensor is highly desired in soft robotics applications.

The performance of the stretchable transducer was evaluated by measuring the capacitance after manually placing different weights on the transducer. First, the sample was clamped and fixed on a linear stretcher, which was used to apply horizontal tensile loads manually. The initial capacitance was measured by an Inductance Capacitance Resistance (LCR) meter (NF ZM 2372) on a logarithmic scale, in a frequency range from 1 to 105 Hz at room temperature (25° C.). Then, a series of known forces was applied and the corresponding capacitances were measured. The same measurement procedures were repeated when the transducer was subjected to different stretching ratios (i.e., 0%, 10%, 20%, and 30%). Finally, the measurement results (i.e., the calibration curves measured at different stretching ratios) were plotted to obtain the variation of capacitance as a function of applied forces at a specific frequency (e.g., 1 kHz). Same to the above-mentioned test for stretchable transducer, the calibration curves of a stretching insensitive transducer should also be stable without variations regardless of the stretching ratios.

To understand the characteristics of the stretchable transducer, it should be noted that a precise way to distinguish soft and hard materials relies on the material's mechanical properties, namely Young's modulus. Although Young's modulus is measured from conventional cylindrical samples subjected to axial tensile stress, Young's modulus is suitable as a standard for the classification of materials as hard or soft materials. From the literature reviewed, materials with Young's modulus smaller than 103 MPa are classified as soft materials.

The effects of the molecular weight (i.e., the length of the polymer chain) on the mechanical properties of electrospinning PVdF microfibers were investigated.

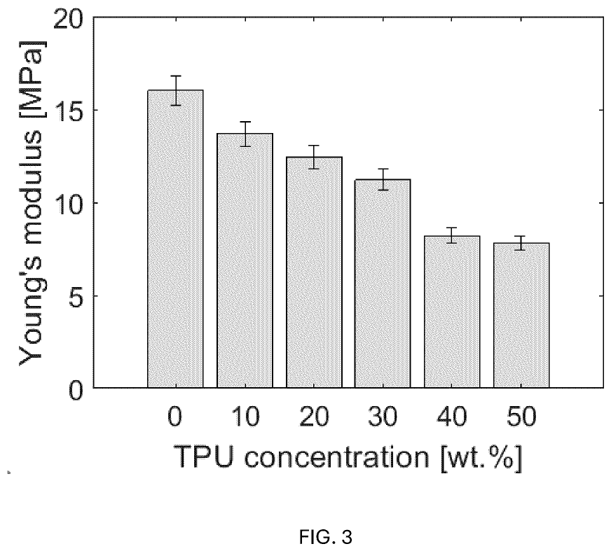

The mechanical properties (i.e., Young's modulus) of conventional electrospinning PVdF-TPU microfibers were tested. From the test result (shown in FIG. 3, which is a graph of Young's modules in MPa vs. TPU concentration in Wt. %), the addition of TPU materials can significantly decrease Young's modulus of the electrospinning microfibers. Samples with TPU concentrations of 40 wt. % and 50 wt. % showed Young's modulus of 8.2 MPa and 7.9 MPa, respectively, which are almost half of the Young's modulus of pure PVdF microfibers (produced by using PVdF materials with molecular weight 395,000). As the test results showed, increasing the TPU concentration from 0 wt. % up to 30 wt. %, Young's modulus of test samples decreased gradually from 16.8 MPa to 11.9 MPa. As mentioned above, a lower Young's modulus means the sample has less resistance to mechanical deformations. The “soft” mechanical characteristics measured from samples indicate PVdF-TPU microfibers are a promising candidate as a soft functional material (i.e., a stretchable transducer with active microfibers) for various applications.

From FDM 3D printed PVdF films which are bulk materials to electrospinning PVdF microfibers which have fiber-like geometries, the Young's modulus reduced sharply, by about three orders of magnitude, from around 10 GPa down to approximately 10 MPa. The addition of soft materials (i.e., TPU) into the electrospinning solution can effectively reduce Young's modulus of electrospinning microfibers to the level of a few MPa. However, the orientations of conventional electrospinning PVdF-TPU microfibers are random. The entanglement of microfibers prevents the further decrease of measured Young's modulus by adding soft materials. Another consideration about the limitation of TPU concentration lower than 50 wt. % comes from the piezoelectric output characteristics of the PVdF-TPU microfibers. There is an inverse relationship between the concentration of TPU and the transducer output, as corroborated by the experimental results. Therefore, the approach according to the present disclosure to decrease the Young's modulus entails the utilization of gap electrospinning to fabricate aligned microfibers.

Based on the working principle of gap electrospinning, the orientation of electrospinning PVdF microfibers is controlled by electric forces generated between electrically positively charged flying microfibers and electrically negatively charged collector electrodes. When the flying microfibers approached the gap between two parallel plate collectors, the electric forces can stretch the charged microfibers in a direction that is in parallel with the electric field. The electrical attraction forces between the positively charged microfibers and negatively charged collector plates' surfaces can help the microfibers to attach to the plates' surface. Therefore, the electrospinning PVdF microfibers were aligned in parallel with the gap width direction. The assumption about the microfibers' direction was proved by the mechanical property test result.

By setting the tensile load direction as the reference direction, the test angle is defined by the angle between the tensile load direction and the fiber length direction. Three test angles were selected including 0°, 45°, and 90°. There were six samples in each group. The Young's modulus of each group was calculated from the tensile test results (i.e., stress-strain curves) and compared with Young's modulus from conventional electrospinning PVdF microfibers which have random fiber orientations.

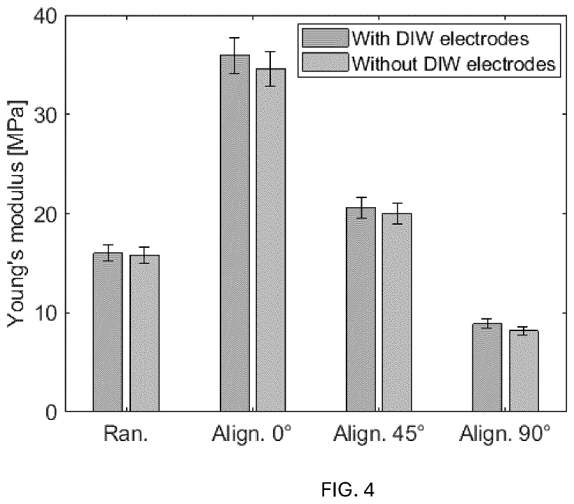

From the experiment results shown in FIG. 4, which is a graph of Young's modulus in MPa vs. angle of alignment, Young's modulus measured from samples with a test angle of 90° is 34.8 MPa which is the highest value among all test groups and higher than that of random orientation samples. With the changing of the test angles from 90° to 45° and then 0°, Young's modulus decreased from 34.8 MPa decreased to 20.6 MPa and 8.6 MPa correspondingly. The results show the anisotropic nature of mechanical properties of aligned electrospinning PVdF microfibers and prove the above-mentioned assumption about the direction of aligned PVdF microfibers. The test results are consistent with the idea that stretching along the length direction of microfibers (i.e., the test angle is) 0°, most of the microfibers were involved to be stretched along their length directions in the view of microscale in which the stretched microfibers can generate the strongest mechanical resistant against the stretching load compared with adding tensile load along other test directions. It is worth noting that Young's modulus measured by applying the tensile load perpendicular to the fiber length direction (i.e., test direction) 90° was the lowest which proves the promise of using gap electrospinning method to produce soft PVdF materials. The desired “soft” mechanical behavior appears only in a specific direction (i.e., test direction) 90°. Therefore, the design of soft stretchable devices should make sure that the externally applied stretching load to the device is in parallel with the most stretchable direction of the aligned PVdF microfibers.

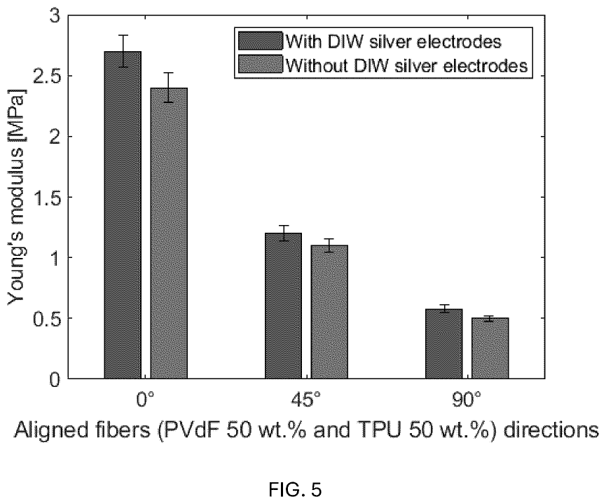

Due to the anisotropic mechanical properties of aligned microfibers, Young's modulus of samples measured from three typical test angles (i.e., 0°, 45°, and) 90° are 2.4 MPa, 1.2 MPa, and 0.5 MPa, respectively (as shown in FIG. 5, which is a graph of Young's modulus in MPa vs. PVdF and TPU microfibers at different fiber alignment directions). The results show that the fabricated piezoelectrically active PVdF-TPU microfibers showed the best stretchability when the stretching load was applied perpendicular to the fiber length direction (i.e., 90° as the test angle). Thus the fabrication methodology of PVdF-TPU microfibers is the integration of the two approaches at the same time (i.e., 1) Customizing the chemical structure by incorporating soft segments to enhance the flexibility of polymer chains or dynamic interactions to dissipate strain energy, and (2) amplifying the ductility of polymer chains through the introduction of a nanoconfinement effect, augments chain dynamics and inhibits the development of sizable crystallites). The gap electrospinning fabrication technique according to the present disclosure takes advantage of electrospinning to directly fabricate piezoelectrically active PVdF microfibers without the need for electric poling as post-processing and to align the produced microfibers in the microscale. To be specific, the microfibers' alignment was achieved through the application of electric forces during the electrospinning process. Compared with the widely used electrospinning setup including a cylinder shape collector, gap electrospinning can simplify the design of the electrospinning setup which saves the need for the cylinder shape collector. The working principle to obtain aligned fibers by using a cylinder shape collector is based on the idea that the rotation movement of the cylinder can help to align the electrospinning fibers mechanically. By comparison, the gap electrospinning technique which relies on electric forces to align the microfibers is more effective.

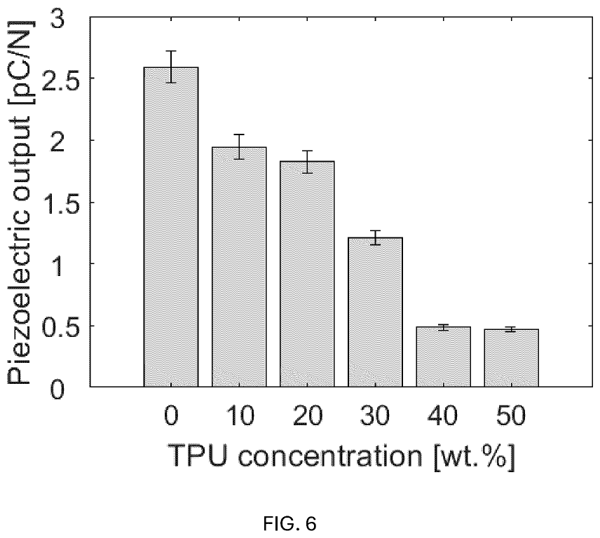

The transducer characteristic, e.g., piezoelectric characteristics, of electrospinning PVdF-TPU microfibers is significantly important for the application of the materials to build soft transducers. The piezoelectric output of electrospinning PVdF-TPU microfibers with different TPU concentrations were measured and the results are shown in FIG. 6, which is a graph of piezoelectric output in pC/N vs. TPU concentration in Wt. %. The results report the mean piezoelectric output of each group measured from six samples to obtain the data with statistical meaning. With the increasing TPU concentrations, the piezoelectric output decreased. It is worth mentioning that the piezoelectric output measured from pure PVdF samples (i.e., 0 wt. % TPU) is about 2.6 pC/N. With the increasing TPU concentrations, the piezoelectric output decreased. The piezoelectric output measured from samples with TPU concentrations at 10 wt. % and 20 wt. % are 1.9 pC/N and 1.8 pC/N, respectively. The piezoelectric output decreased to 1.23 pC/N corresponding to samples with TPU concentration at 30 wt. % and decreased to 0.5 pC/N for samples with TPU concentration at 40 wt. %. The piezoelectric output remained stable at around 0.5 pC/N even when the TPU concentration was further decreased to 50 wt. %.

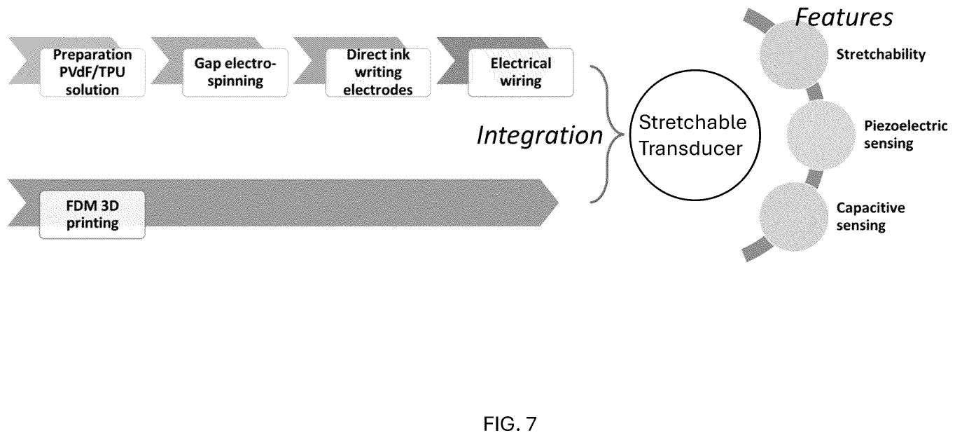

The stretchable piezoelectric pressure sensor and 3D architecture have been fabricated and demonstrated herein. The fabrication process consists of three main steps as illustrated in FIG. 7, which is a schematic of fabrication process for the stretchable electrospinning PVdF-TPU microfiber-based transducer of the present disclosure including the FDM 3D printing of the top, middle, and bottom substrates 152a, 152b, and 152c, respectively (see FIG. 1b). Initially, PVdF pellets, e.g., 750 mg, and TPU filament (Shore hardness 60 A), e.g., 750 mg, were dissolved into DMF/acetone (volume ratio 4:6) 10 mL solvent mixture to prepare a 15 wt. % solution for electrospinning. Next, gap electrospinning was performed to produce an aligned PVdF-TPU microfibers membrane. The structure of the gap electrospinning setup together with the parameters used in electrospinning is described herein. After gap electrospinning, direct ink writing was applied to print stretchable conductor silver ink on the surface of the electrospinning microfiber membrane to obtain design electrode patterns. The electrospinning PVdF-TPU microfibers membrane was sandwiched between two silver electrodes on the top and bottom surfaces, respectively. Finally, electrical wiring is a necessary procedure to build an electrical connection between the sensors and signal conditioning circuits. It is worth mentioning that the microfiber's length direction should be identified first to determine the direction that is perpendicular to the fiber length direction, which is named the stretchable direction. From the mechanical property test results, the lowest Young's modulus is shown when stretching the aligned microfibers following the direction perpendicular to the fiber length direction. In the transducer design, aligned microfibers-based stretchable transducers should have the microfibers' stretchable direction in parallel with the external stretching load direction to obtain the best stretchability. As discussed above, the top, middle, and bottom substrates 152a, 152b, and 152c, respectively (see FIG. 1b), are made from the FDM 3D printing separately, while the PVdF-electrode subassemblies 154 and 156 (see FIG. 1b) are made utilizing a combination of gap electrospinning to make the PVdF-TPU microstructures (e.g., 154b, see FIG. 1b), and DIW to deposit electrodes (e.g., 154a and 154b, see FIG. 1b) on the top and bottom surfaces of the PVdF-TPU microstructures (e.g., 154b, see FIG. 1b). The FDM 3D printing technique is used to print soft 3D architectures using TPU filament (Shore hardness 60 A). The features of the soft TPU filament together with the introduction to the modification of an FDM 3D printer for printing soft materials, and printing parameters are described herein. The third step is the integration of electrospinning PVdF-TPU microfibers-based sensors with FDM 3D printed soft 3D architecture of the substrates to obtain stretchable piezoelectric pressure sensors. The final integration/packaging step was done by using a polymer such as Polydimethylsiloxane (PDMS) to fully encapsulate and isolate from the environmental disturbances.

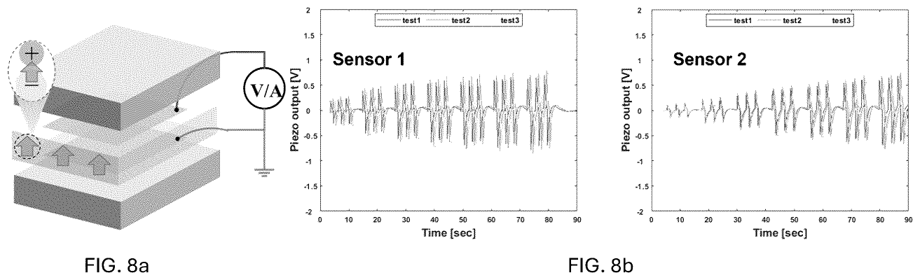

Eight different devices were studied based on disposition of dipoles generated during the gap electrospinning process and based on the connectivity of the electrodes (e.g., 154a and 154c and the electrodes of the PVdF-electrode subassemblies 154 and 156, see FIG. 1b). These eight devices included: 1) Embodiment 1—where only one PVdF-electrode subassembly 154, see FIG. 1b, is situated with the dipole generated during the electrospinning process oriented along a first direction; 2) Embodiment 2—where only one PVdF-electrode subassembly 154, see FIG. 1b, is situated with the dipole generated during the electrospinning process oriented along a second direction, opposite the first direction; 3) Embodiment 3—where two PVdF-electrode subassemblies 154 and 156, see FIG. 1b, are situated with the dipoles generated during the electrospinning process for both PVdF-electrode subassemblies 154 and 156, see FIG. 1b, are oriented along the first direction and the electrodes (e.g., 154a and 154c of the PVdF-electrode subassembly 154 and the electrodes of the PVdF-electrode subassembly 156, see FIG. 1b, are coupled in a series manner; 4) Embodiment 4—where two PVdF-electrode subassemblies 154 and 156, see FIG. 1b, are situated with one of the dipoles generated during the electrospinning process for, e.g., PVdF-electrode subassembly 154, see FIG. 1b, is oriented along the first direction, while the other dipoles of PVdF-electrode subassembly 154 are oriented along the second direction, and where the electrodes (e.g., 154a and 154c of the PVdF-electrode subassembly 154 and the electrodes of the PVdF-electrode subassembly 156, see FIG. 1b, are coupled in a series manner; 5) Embodiment 5—where two PVdF-electrode subassemblies 154 and 156, see FIG. 1b, are situated with the dipoles generated during the electrospinning process for both PVdF-electrode subassemblies 154 and 156, see FIG. 1b, are oriented along the second direction and the electrodes (e.g., 154a and 154c of the PVdF-electrode subassembly 154 and the electrodes of the PVdF-electrode subassembly 156, see FIG. 1b, are coupled in a series manner; 6) Embodiment 6—where two PVdF-electrode subassemblies 154 and 156, see FIG. 1b, are situated with the dipoles generated during the electrospinning process for both PVdF-electrode subassemblies 154 and 156, see FIG. 1b, are oriented along the first direction and the electrodes (e.g., 154a and 154c of the PVdF-electrode subassembly 154 and the electrodes of the PVdF-electrode subassembly 156, see FIG. 1b, are coupled in a parallel manner; 7) Embodiment 7—where two PVdF-electrode subassemblies 154 and 156, see FIG. 1b, are situated with one of the dipoles generated during the electrospinning process for, e.g., PVdF-electrode subassembly 154, see FIG. 1b, is oriented along the first direction, while the other dipoles of PVdF-electrode subassembly 154 are oriented along the second direction, and where the electrodes (e.g., 154a and 154c of the PVdF-electrode subassembly 154 and the electrodes of the PVdF-electrode subassembly 156, see FIG. 1b, are coupled in a parallel manner; and 8) Embodiment 8—where two PVdF-electrode subassemblies 154 and 156, see FIG. 1b, are situated with the dipoles generated during the electrospinning process for both PVdF-electrode subassemblies 154 and 156, see FIG. 1b, are oriented along the second direction and the electrodes (e.g., 154a and 154c of the PVdF-electrode subassembly 154 and the electrodes of the PVdF-electrode subassembly 156, see FIG. 1b, are coupled in a parallel manner. Schematics of these eight embodiments are shown in FIGS. 8a, 9a, 10a, 10c, 10e, 11a, 11c, and 11e along with transducer outputs (e.g., graphs of piezoelectric outputs in V vs. time in seconds in response to changes in the environment) as shown in FIGS. 8b, ba, 10b, 10d, 10f, 11b, 11d, and 11f.

When there is a force exerted on the transducer, electrical charges are produced on the materials' surface. By connecting the transducer to a circuit, the voltage potential across the transducer can drive charges in the circuit to flow (i.e., electrical current), which initiated the mechanical-to-electrical signal conversion. Accordingly, the influence of the electrical configuration methods of one or two PVdF-electrode assemblies (e.g., see PVdF-electrode assemblies 154 and 156, see FIG. 1b) on the transducers' output was investigated. The transducers were tested by applying a series of known forces in a range of 1 N to 7 N with a 1 N increment on the one or two PVdF-electrode assemblies (e.g., see PVdF-electrode assemblies 154 and 156, see FIG. 1b). The observation focused on finding the best types of configurations for the system in producing optimum transducer output.

In the first embodiment, the experiment was done by measuring the transducer output of two single sensors individually. The connection methods associated with the polarity of piezoelectric materials shown in FIGS. 8a and 9a, were named as forward connection and reverse connection methods, respectively. Two transducers were used to generate the signals for the first and second embodiments. The transducer output of each transducer was measured with forward and reverse connection methods, respectively. The measured transducer output from transducers 1 and 2 (shown as sensors 1 and 2) are shown in FIGS. 8b and 9b corresponding to signals measured by using forward connection and reverse connection methods, respectively. The transducer output from each transducer using the same connection method was repeatedly measured three times and plotted in the same figure to show the measurement results have a good reproducibility and stability. Signals plotted in the same figure were identified by using different colors and marked with different test numbers. Compared to the piezoelectric output shown in FIGS. 8b and 9b, the magnitudes of the signals are the same, but the polarity of the signals are reversed which are associated with electrical connections for both transducers.

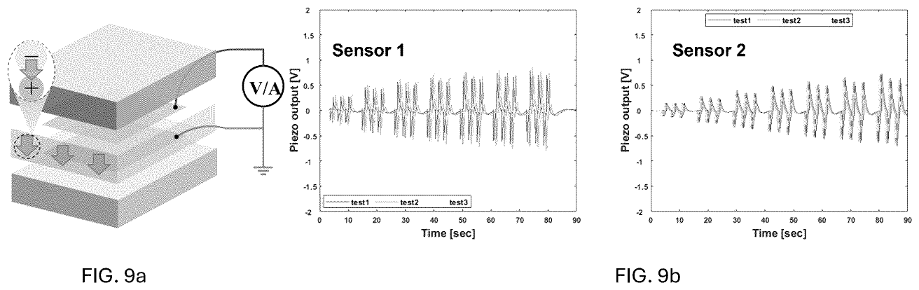

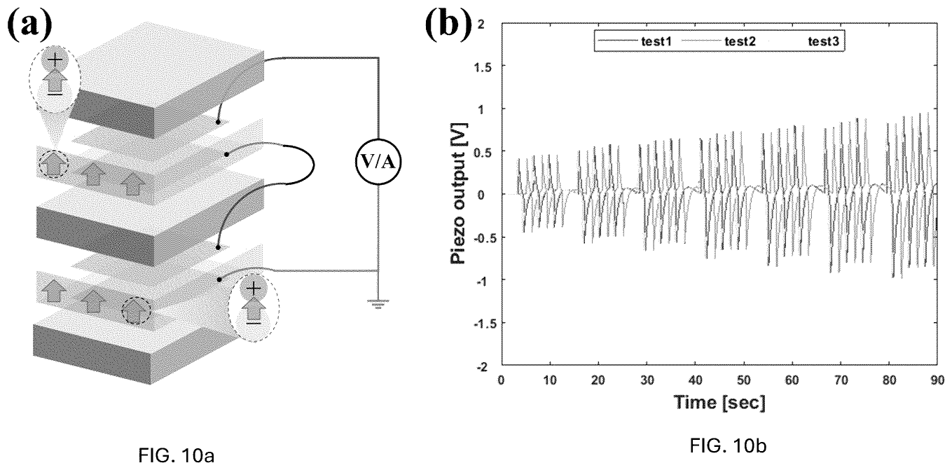

The second stage experiment was to study the transducer output of two transducers in the series of electrical configuration. The results are shown in FIGS. 10a-10f. Due to the above-mentioned forward and reverse connection methods for a single transducer, there are three different methods to connect two transducers in series, which are shown in FIGS. 10a, 10c, and 10e, and their corresponding transducer output signals are shown in FIGS. 10b, 10d, and 10f, respectively. It is found that increasing the number of transducers electrically connected in series did not affect the amplitude of the voltage output. The same transducer voltage output was attributed to the current source connected in a series connection. When the current sources were connected in series, the output voltage was generated at the same output which was irrelevant to the number of current sources added between them.

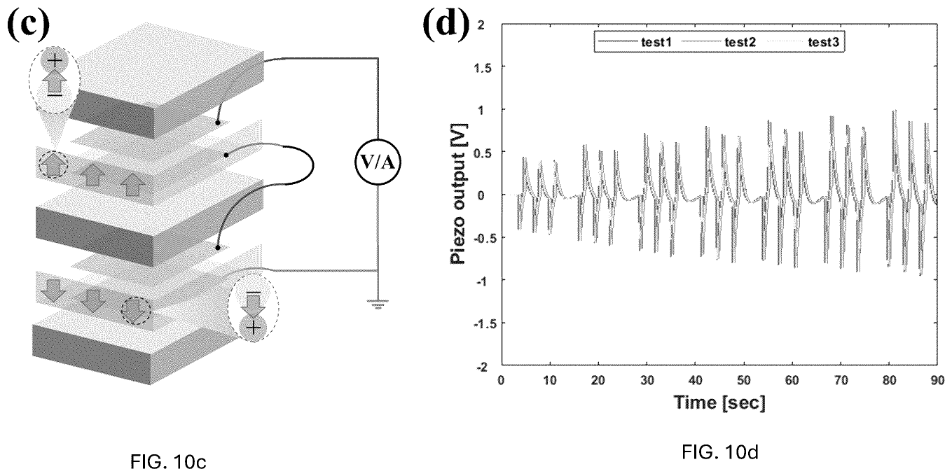

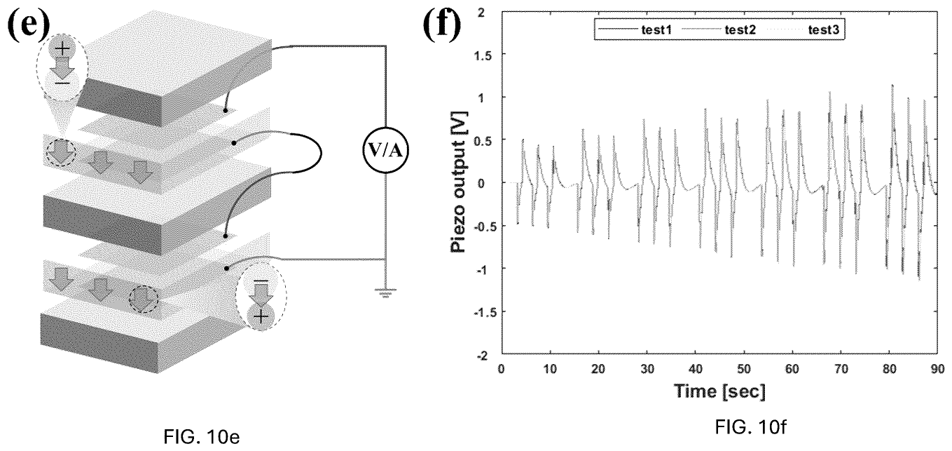

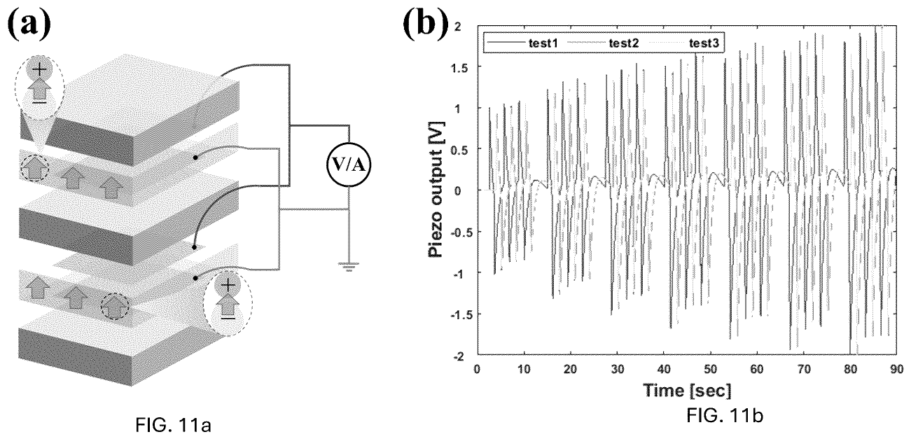

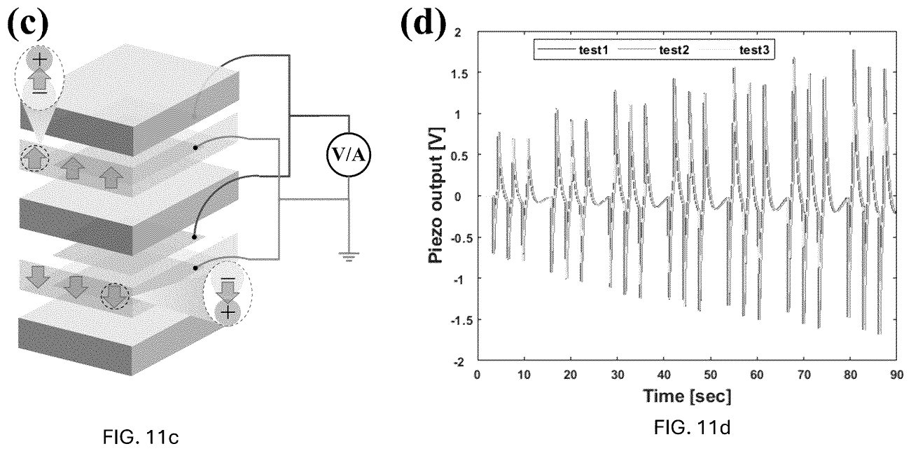

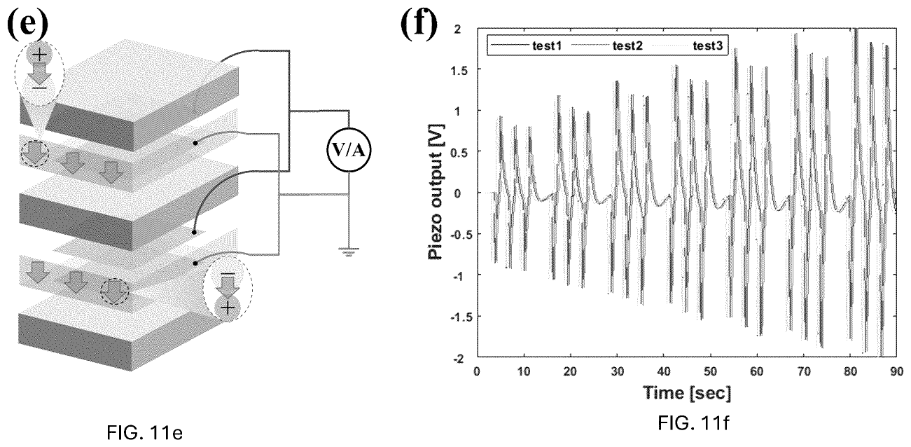

Two transducers with an electrical configuration in the parallel connection method are shown in FIGS. 11a, 11c, and 11e, and their corresponding transducer output signals are shown in FIGS. 11b, 11d, and 11f, respectively. The transducers' output voltage for two transducers in parallel connection are about equal to the summation of the output signals measured from two single transducer. When one sensor in the parallel connection configuration was reversely connected into the system as shown in FIG. 11c, the magnitude of the transducer output (shown in FIG. 11d) decreased slightly by about 0.25 V. When both transducer were reversely connected in the parallel connection configuration as shown in 11e, the measured transducer output (shown in FIG. 11f) has the same magnitude, but reversed polarity compared to the signal measured from the system with both transducers were forwardly connected in parallel. Therefore, the experiment results show the sensing system with two PVdF-based transducers in the parallel connection configuration can generate optimized transducer output signals.

The influence of 3D printed TPU structure on the transducer output of PVdF-based transducers was also studied. The structure of the transducer, according to one embodiment of the present disclosure, is shown in the side panel of FIG. 1b, which is a three-layer structure including two PVdF-electrode assemblies 154 and 154 (see FIG. 1b) sandwiched between three TPU substrates 152a, 152b, and 152c. To study the mechanical deformation of the sensing system under compression load, a simple mechanical model is introduced in which three springs with different spring constants (k₁, k₂, and k₃) are connected in series for an embodiment where only one PVdF-electrode assembly (e.g., 154, see FIG. 1b) is used sandwiched between two TPU substrates. When the sensor is subjected to a compression load in the thickness direction, X is the total displacement of the system which is the summation of displacement of each layer, as provided in Eq. 1.

$$X = {x}_{1} + {x}_{2} + {x}_{3} \qquad ( 1 )$$

where x₁, and x₃ correspond to the displacement of the top and bottom TPU layers, respectively, and x₂ is the displacement of the PVdF-electrode assembly (e.g., 154, see FIG. 1b). The total spring constant of the system is K, as provided in Eq. 2.

$$\frac{1}{K} = \frac{1}{{k}_{1}} + \frac{1}{{k}_{2}} + \frac{1}{{k}_{3}} \qquad ( 2 )$$

where the spring constant of the PVdF-electrode assembly (e.g., 154, see FIG. 1b) is k₂, and the spring constant for the other two TPU films are k₁ and k₃, respectively. The spring constants will change when the distortion exceeds a critical value. This implies that when the film reaches a certain thickness, it becomes more rigid. Such a hardening phenomenon occurs on plastic films. According to the present disclosure, however, all layers are experiencing elastic deformation induced by compression mechanical inputs, otherwise, the sensor output will lose reproducibility and stability. The externally applied compression force is F. The displacement of each spring (film) can be derived by using the following relationship, provided by Eqs. 3 and 4.

$$F = - {F}_{1} = - {F}_{2} = - {F}_{3} \qquad ( 3 )$$

$$F = - {k}_{1} {x}_{1} = - {k}_{2} {x}_{2} = - {k}_{3} {x}_{3} . \qquad ( 4 )$$

When the sensing system subjects to an externally applied compression force, the forces generated by each layer against the external force are equal with opposite signs (i.e., opposite direction compared with the external force) regardless of the number of layers in the system. The relationship between externally applied force and the transducer output is described by Eq. 5.

$${D}_{3} = {d}_{33} {σ}_{3} \qquad ( 5 )$$

where D₃ is the surface charge density (pC/m²), d₃₃ is a transducer coefficient, and σ₃ is the externally applied stress on the transducer. Based on the above equation, the number of charges Q₃ generated in response to externally applied compression force F₃ is described by Eq. 6.

$${Q}_{3} = {D}_{3} {A}_{E} = {d}_{33} {A}_{E} \frac{{F}_{3}}{{A}_{contact}} \qquad ( 6 )$$

where A_{E} is the area of electrodes, A_{contact} is the contact area of the experiment setup and the sensor where the force F₃ is applied. The number of charges Q₃ generated did not change, which means the addition of a 3D printed TPU layer will not change the transducer output.

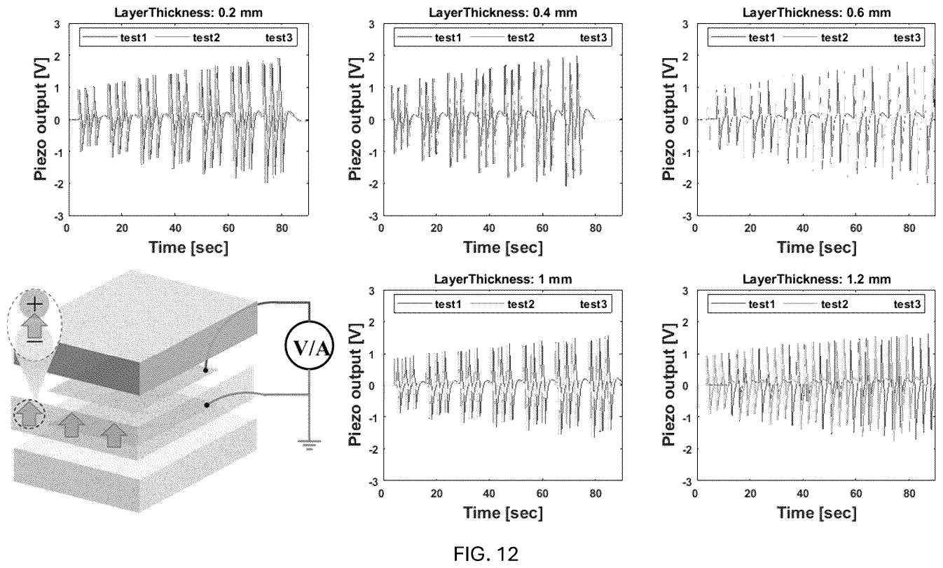

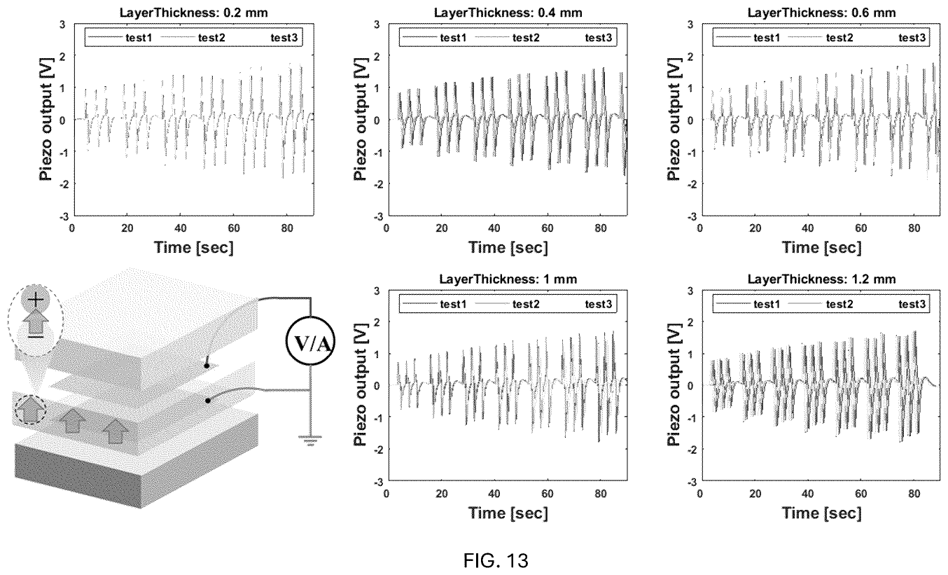

Next, the influence of the thickness of the FDM 3D printed substrate on the transducer output of a single PVdF-electrode assembly (e.g., 154 see FIG. 1b) was studied. The results of the influence of the bottom and top layers are shown in FIG. 12 and FIG. 13, respectively, which are schematics of the first enumerated embodiment discussed above with one PVdF-electrode assembly with one dipole orientation and the accompanying transducer outputs (e.g., piezoelectric output) for different thicknesses of FDM 3D printed TPU substrates, where FIG. 12 provides variations of the bottom substrate and FIG. 13 provides variations of the top substrate. The thickness of the 3D printed layers (TPU substrates) increased gradually from 0.2 mm to 0.6 mm with 0.2 mm as the increment, and then two thicker layers with thicknesses of 1.0 mm and 1.2 mm were also tested, transducer outputs of all of which are shown in FIGS. 12 and 13. With the increase of the layer thickness, the amplitude of the piezoelectric output did not show any clear variation trends for both the boom and the top layer thickness test. For each thickness, three tests were conducted.

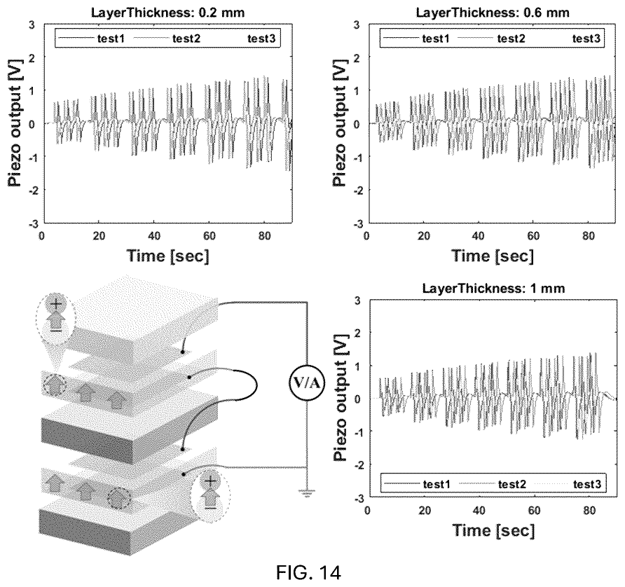

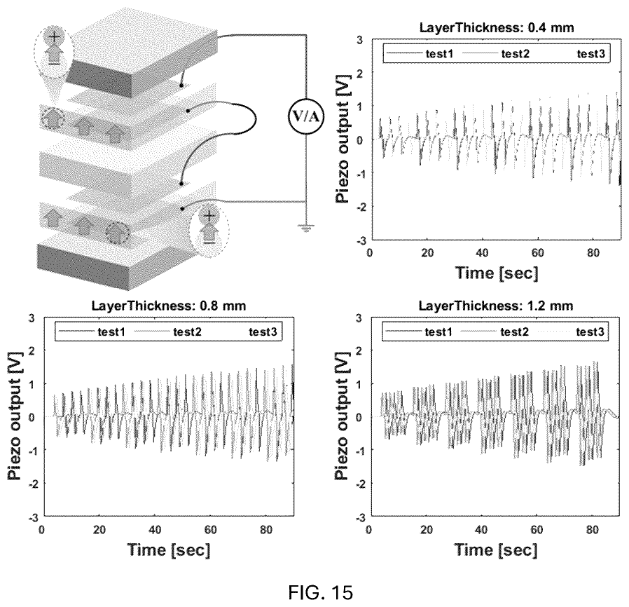

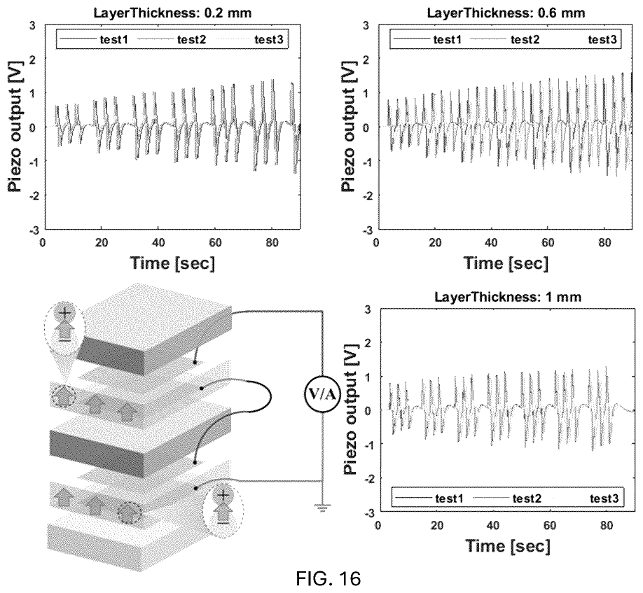

The second stage of experiment tested the influence of FDM 3D printed layer thickness of substrate (i.e., top, middle, and bottom substrates 152a, 152b, and 152c, respectively, see FIG. 1b) on the transducer output of a sensing system including two PVdF-electrode assemblies (e.g., 154 and 156, see FIG. 1b) in series electrical configuration, i.e., the third enumerated embodiment. The mechanical structure of the sensing system from top to bottom includes 1) top TPU substrate, 2) first PVdF-electrode assembly, 3) middle TPU substrate, 4) second PVdF-electrode assembly, and 5) bottom TPU substrate, which are laminated together. The experiment results about the influence of the top layer, middle layer, and bottom layer thickness are shown in FIG. 14, FIG. 15, and FIG. 16, respectively.

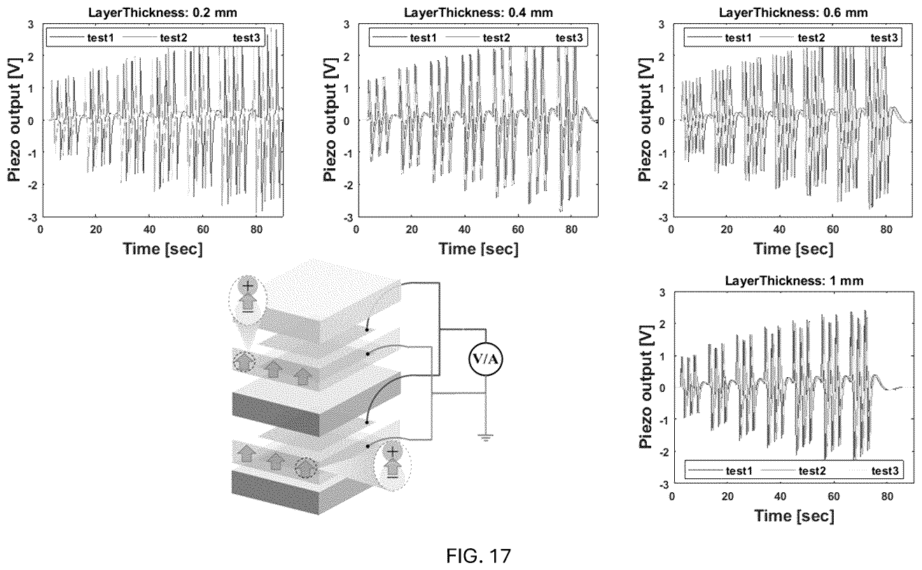

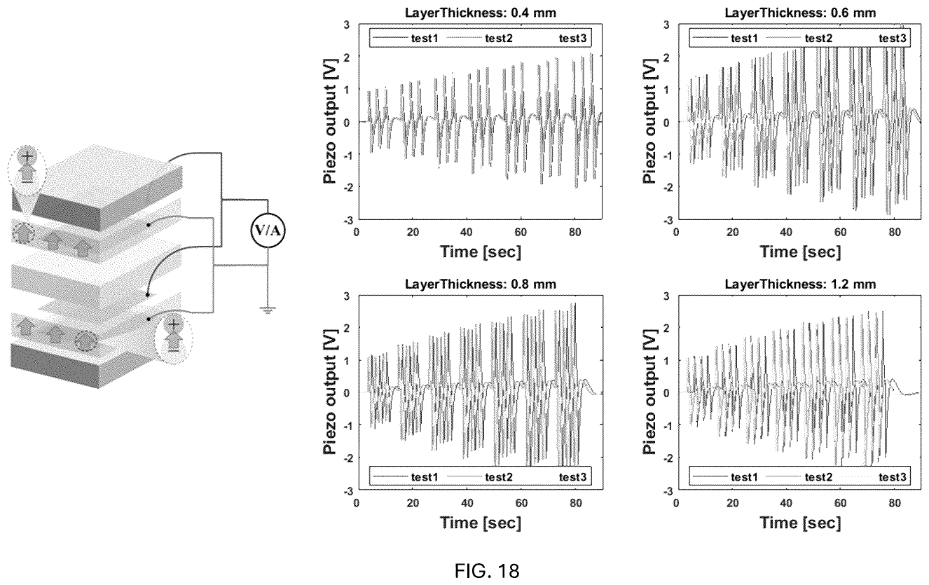

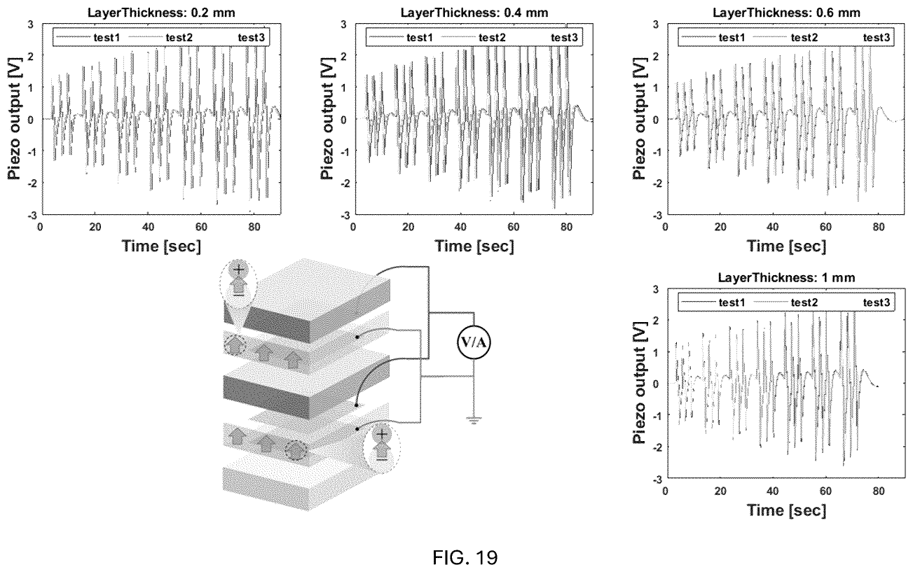

The third stage of experiment tested the influence of FDM 3D printed layer thickness of substrate (i.e., top, middle, and bottom substrates 152a, 152b, and 152c, respectively, see FIG. 1b) on the transducer output of a sensing system including two PVdF-electrode assemblies (e.g., 154 and 156, see FIG. 1b) in parallel electrical configuration, i.e., the sixth enumerated embodiment. The mechanical structure of the sensing system from top to bottom includes 1) top TPU substrate, 2) first PVdF-electrode assembly, 3) middle TPU substrate, 4) second PVdF-electrode assembly, and 5) bottom TPU substrate, which are laminated together. The experiment results about the influence of the top layer, middle layer, and bottom layer thickness are shown in FIG. 17, FIG. 18, and FIG. 19, respectively.

The idea of integration of electrospinning microfibers with DIW of electrodes with FDM 3D printed soft substrates can add functionality and stretchability to PVdF-TPU microfiber-based transducers. The stretchable transducers have multiple sensing mechanisms which are piezoelectric-type sensing and capacitive sensing mechanisms. The piezoelectric sensing capability is attributed to the application of PVdF materials as the sensing component. After the integration, PVdF materials were embedded within 3D printed soft TPU structures as discussed above. The 3D printed soft TPU structures can influence the transducer output of PVdF materials, which can finally influence the sensor performance (i.e., sensitivity).

Besides the piezoelectric sensing capability, the fabricated transducers also have capacitive sensing capability due to the designed sensors' structure consisting of multiple layers of dielectric materials sandwiched between two electrodes as capacitors. The multiple layers of dielectric materials were composed of electrospinning PVdF-TPU microfibers layers and a 3D printed TPU layer. The influence of the thickness of 3D printed TPU layer on the sensor performance was studied by measuring the transducer output and capacitance.

Therefore, the key to the stretchability of 3D printed structures relies on the application of soft TPU filament during the electrospinning process and the designed serpentine structure. The geometric parameters in the designed serpentine structure determined the stretchability of the structure, which can also influence the sensor performance under different sensing mechanisms including piezoelectric sensing and capacitive sensing mechanisms.

The fabricated stretchable transducer of the present disclosure is composed of four areas with different functionalities including the flat sensing area, serpentine area, electric connection area, and clamping area, as discussed above, with reference to FIG. 1b. The sensing area is responsible for detecting externally applied forces with hybrid sensing mechanisms. The serpentine area is mechanically stretchable which is designed to accommodate deformations caused by externally applied stretching load. The term “mechanically stretchable” emphasizes the stretchability is attributed to the design of the mechanical structure. By comparison, the term “intrinsically stretchable” means the stretchability originated from the soft nature of the materials (i.e., low Young's modulus). Thus, the term “mechanically stretchability” is used to describe the stretchability of the serpentine structure and the fabricated sensors.

Based on the capacitive sensing mechanisms, the creation of stretchable pressure sensors was implemented simply by using various types of stretchable silver conductors and 3D printed TPU layers as dielectric elastomers. However, one key limitation remains which is the substantial alteration of the calibration curve for the pressure sensing performance when the sensor is under stretching. The alternation of the calibration curve arises from the inherent coupling of mechanical deformations along different directions of a structure. Hence, a longitudinal strain can cause normal compression, similar to the deformation from a normal force. The undesired normal compression greatly complicates the application of such sensors for quantitative measurements.

The influence of the middle substrate thickness in the 3D printed serpentine structure on the sensor performance was further studied. For the design of stretchable 3D architectures, the thickness of the middle layer in the sensing area varied by selecting three different values (i.e., 0.6 mm, 1.2 mm, and 2.0 mm). Besides the middle layer thickness in the sensing area in 3D printed architectures, other dimensions of the architectures were kept constant.

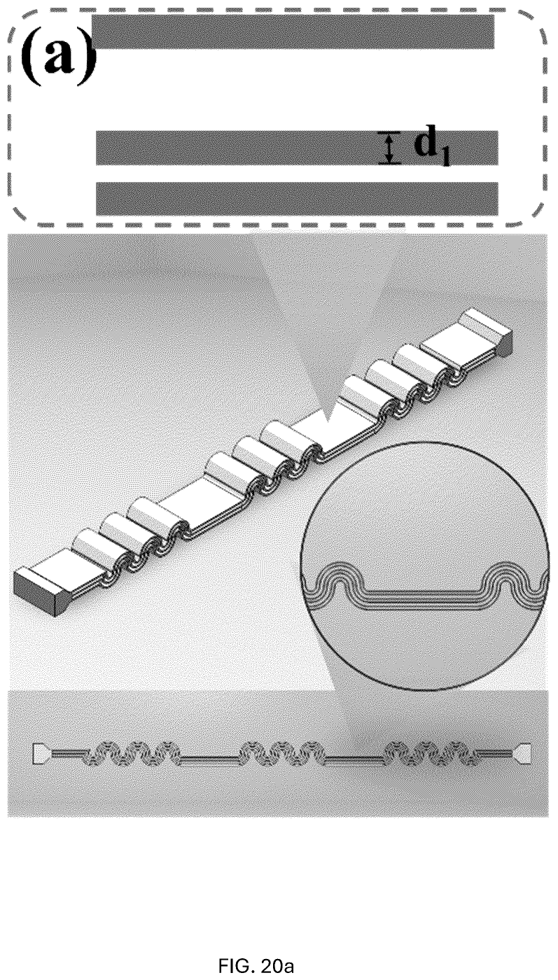

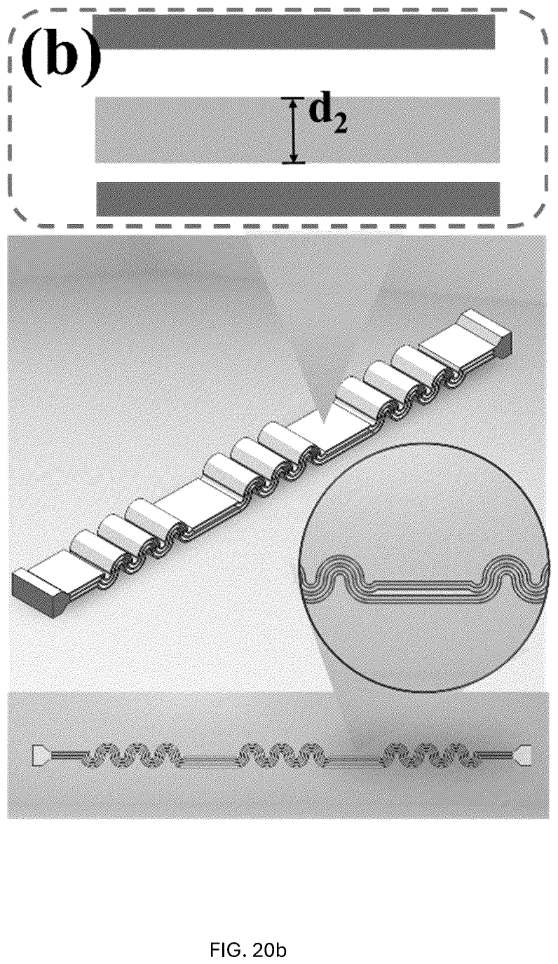

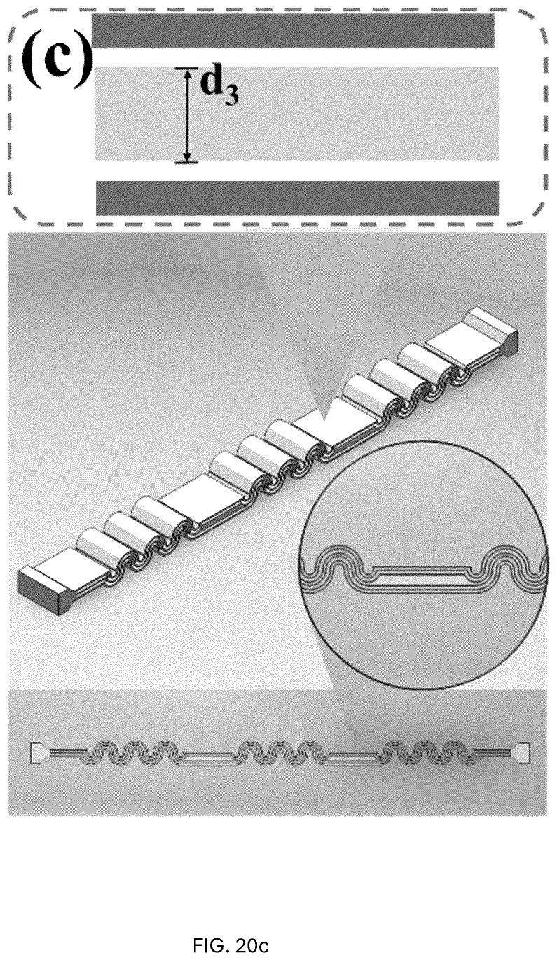

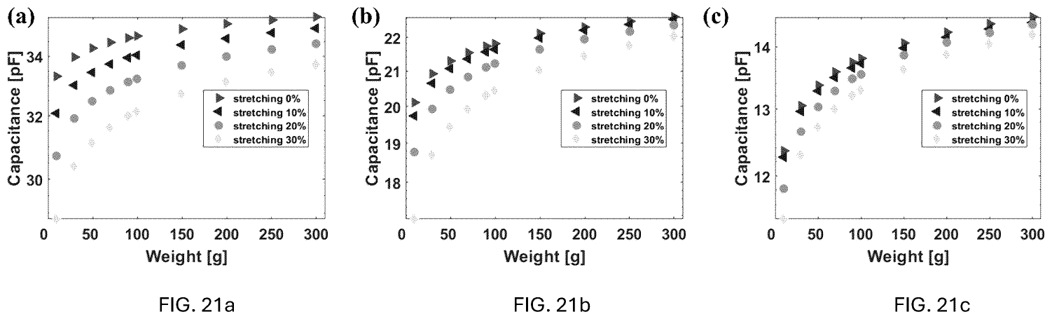

The sensor performances measured as stretchable capacitive pressure sensors are shown in FIGS. 20a, 20b, and 20c, which are schematics of the transducer with varying middle substrate thicknesses (152b, see FIG. 1b). The sensor performance was measured by applying a series of known forces on the flat sensing area and measuring the corresponding sensor capacitances. The force applied was regarded as a “static force”. The same test procedures were repeated when the sensor was subjected to different stretching ratios (i.e., 10%, 20%, and 30%). For the sensors with three different designed structures, their performances were tested and are shown in FIGS. 21a, 21b, and 21c, respectively. Ideally, the capacitance measured at a fixed applied weight should also be a fixed value that corresponds to the applied weight regardless of the stretching ratios which are the function of a stretching-insensitive capacitive sensor. The results show that the capacitance measured as a function of applied force determined under different stretching ratios were quite different for the sensors with middle layer thickness of 0.6 mm, and 1.2 mm. With the increase of the middle layer thickness, the curves which described the relationship between the applied force and measured capacitance became closer and closer, which indicated the sensor tended to become a stretching-insensitive capacitive sensor.

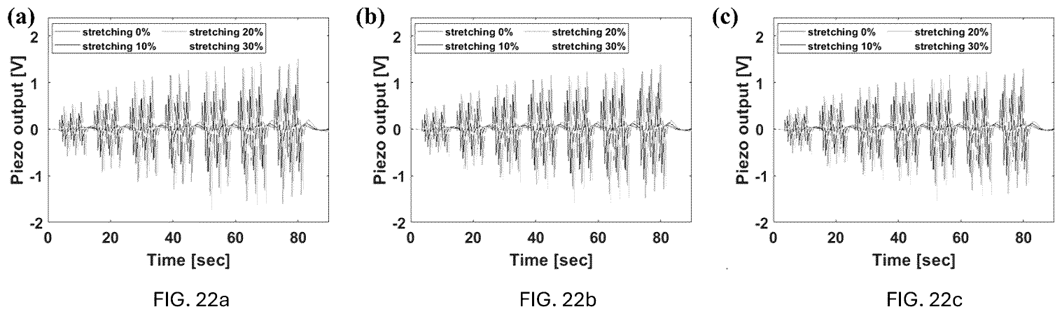

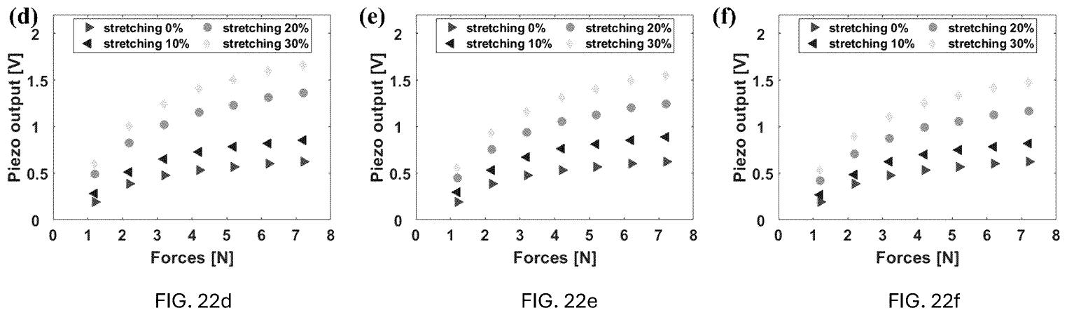

The fabricated sensors also have a piezoelectric sensing mechanism. The electrospinning PVdF-TPU microfibers are responsible for the piezoelectric output. Instead of measuring the capacitance when a known force was applied to the sensing area, the piezoelectric output was measured by applying a series of known forces dynamically. Herein, the term “dynamic forces” was used to distinguish the applied load for piezoelectric output measurement from above mentioned “static forces” applied for capacitance measurement. During the piezoelectric output measurement, the dynamic force was applied at a frequency of 0.5 Hz. specifically, a known force was applied on the sensing area which was held for 1 second before releasing. After the applied force was released for 1 second, the same magnitude of force was applied again. When applying dynamic forces, the sensor was subjected to cyclic loading-and-unloading mechanical inputs. Based on the characteristic of piezoelectric sensor output, a spike was measured corresponding to an applied force and another spike with reverse polarity was measured corresponding to the releasing of the applied force. During the experiment, the performances of the stretchable piezoelectric sensors with different designed structures (i.e., different thicknesses in the middle layer of the sensing area) were determined by applying a series of known forces dynamically while measuring the piezoelectric output at different stretching ratios. The piezo output in V vs time in seconds results were shown in FIGS. 22a, 22b, 22c for middle layer thickness of 0.6 mm, 1.2 mm, and 2.0 mm, respectively, where the piezo output in V vs. force in N are shown in FIGS. 22d, 22e, and 22f, for middle layer thickness of 0.6 mm, 1.2 mm, and 2.0 mm, respectively. The expectation for the performance of the fabricated sensor to be a stretching-insensitive piezoelectric pressure sensor is similar to that of stretching insensitive capacitive pressure sensor.

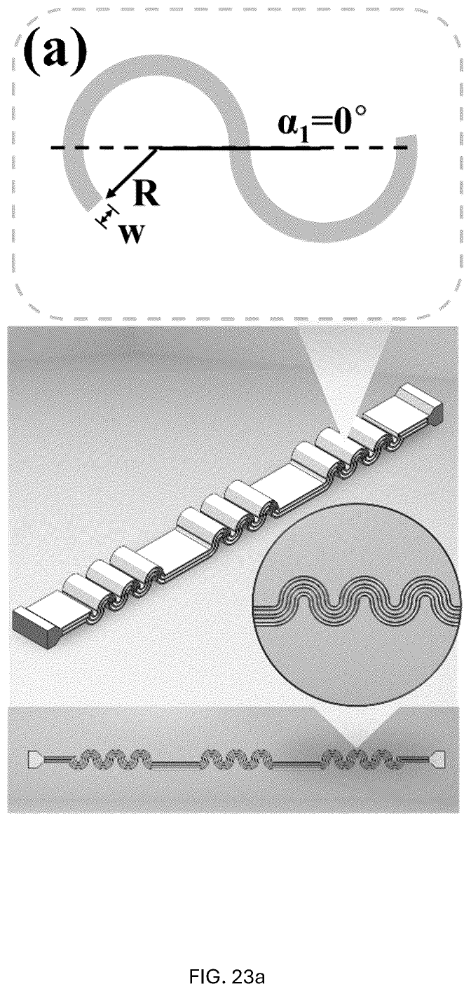

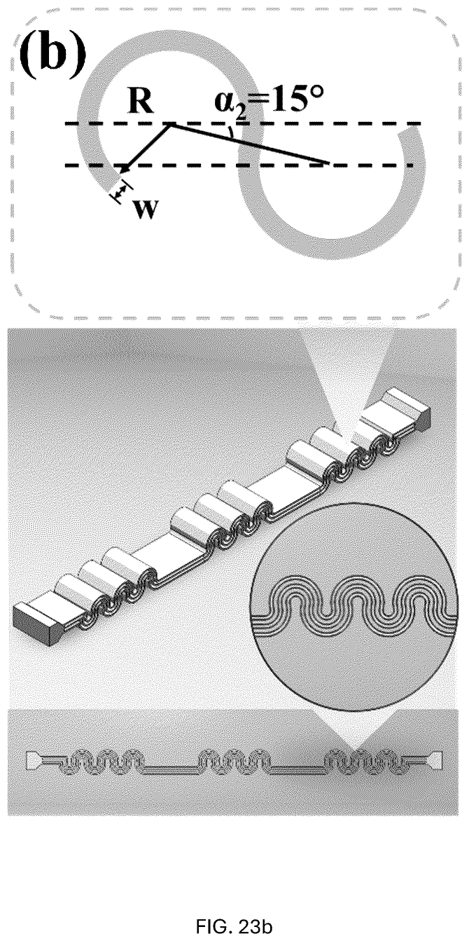

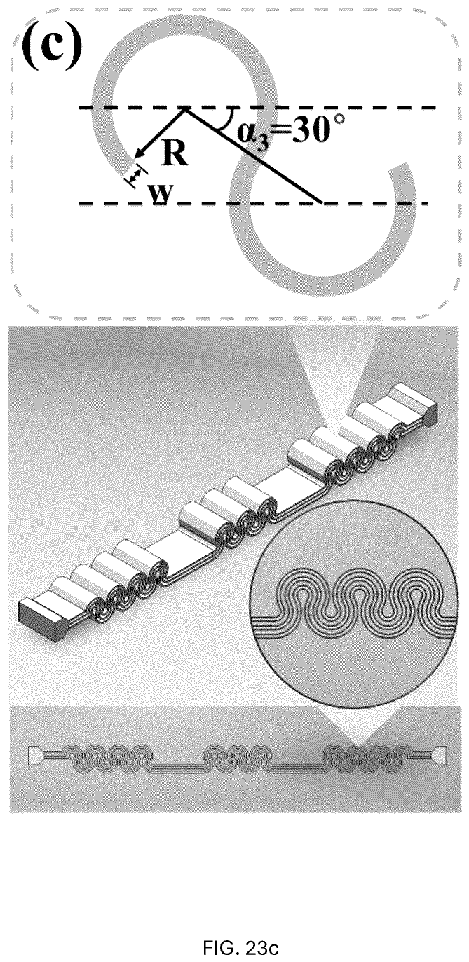

Besides the center layer thickness in the design of the 3D architecture, the influence of serpentine structures on the sensor performance was studied. The parameter studied that can influence the geometry of the serpentine structure is defined in FIGS. 23a, 23b, and 23c, which are schematics of one embodiment of a transducer according to the present disclosure showing different angles of the serpentine areas. For the design of stretchable 3D architectures, the angle marked as a in the stretching accommodation area varied by selecting three different values (i.e., 0°, 15°, and) 30°. Besides the angle in 3D printed architectures, other geometry related parameters of the architectures were kept constant.

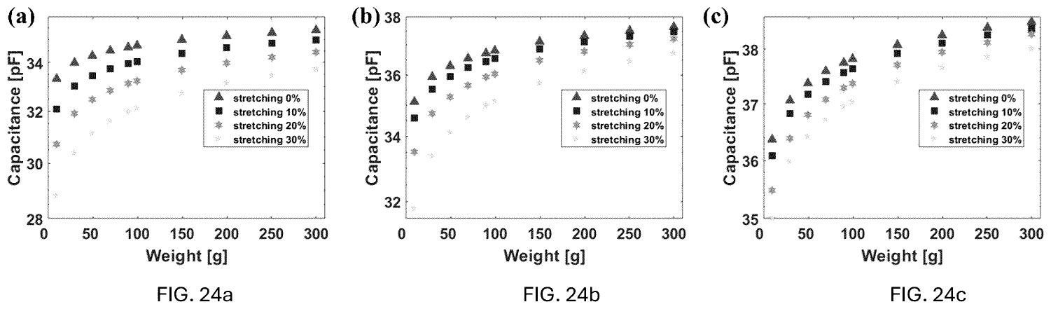

Accordingly, attempts for decoupling the strain's effect on the pressure sensing were done by decreasing the areal stiffness of the serpentine structure to isolate the sensor units from the applied strain. The strain energy is dissipated only by the serpentine areas surrounding the sensing areas. When the 3D printed TPU materials experienced elastic deformation during stretching, the layer thickness decreased resulting in the increasing of the capacitance shown in FIGS. 24a, 24b, and 24c which are graphs of capacitance vs. weight of the transducer for the three angles shown in FIGS. 23a, 23b, and 23c, respectively. The initial capacitance increased with the increasing of stretching ratios. From the results shown in FIG. 24a, the curves which described the relationship between capacitance and applied weight measured at different stretching ratios are different. The results indicate that the stretching-induced deformation was not totally dissipated by the mechanical structure deformation of the serpentine structure. At least part of the stretching induced deformation was accommodated by the elastic deformation of TPU materials in the flat sensing area. With the increasing of the studied angle from 0° to 15°, the ability of the serpentine structure to accommodate stretching induced deformation improved. From FIG. 24b, the capacitance as a function of the applied weight measured from the sensor subjected to 10% stretching ratio were very close to the measurement result at 0% stretching ratio. With the further increasing of the stretching ratio, the differences between the capacitances of the same sensor subjected to the same applied weight but measured at different stretching ratios enlarged. By comparison, the data measured from the sensor with the studied angle at 30° in the serpentine structure have the smallest deviations, which means that less deformation occurred in the flat sensing area caused by the stretching.

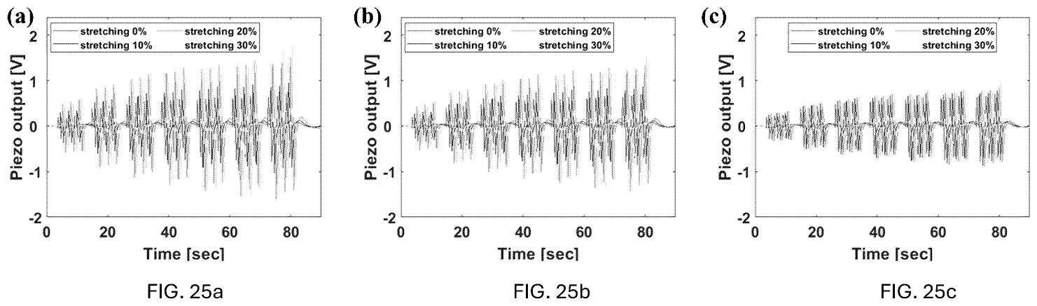

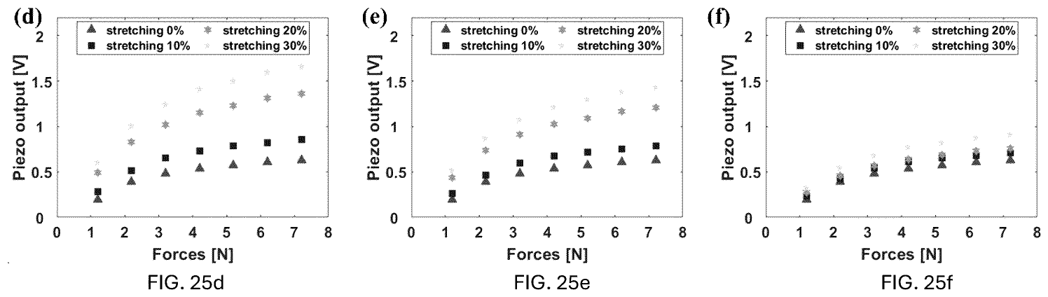

When the same sensors with the above-mentioned differences in the design of their serpentine structures (i.e., different angles), the sensors' performance was measured and evaluated as piezoelectric pressure sensors. The piezo output in V vs. time in seconds results are shown in FIGS. 25a, 25b, and 25c, while piezo output in V vs. force in N are shown in FIGS. 25d, 25e, and 25f, each respectively, for the three serpentine angles discussed above. The amplitude of piezoelectric output voltage and the applied forces were plotted to obtain the calibration curves of the sensors studied. For the same sensor measured at different stretching ratios, the amplitude of the piezoelectric output increased with the increase of stretching ratios. The differences among the series of calibration curves measured from the same sensor at different stretching ratios were quite a lot from FIGS. 25e and 25d, which correspond to sensors with angles of 0° and 15° in the design of the serpentine structures. From FIG. 25f, the calibration curves of sensors with angle α₃=30° in the designed serpentine structure are close especially measured at 0%, 10%, and 20% stretching ratios, which means the sensor behaved like stretching insensitive piezoelectric pressure sensors when the stretching ratio limited within 20%.

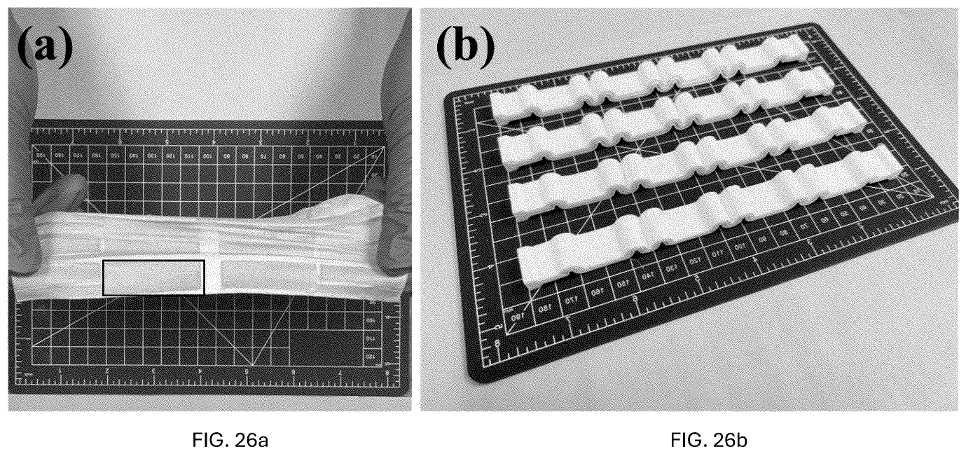

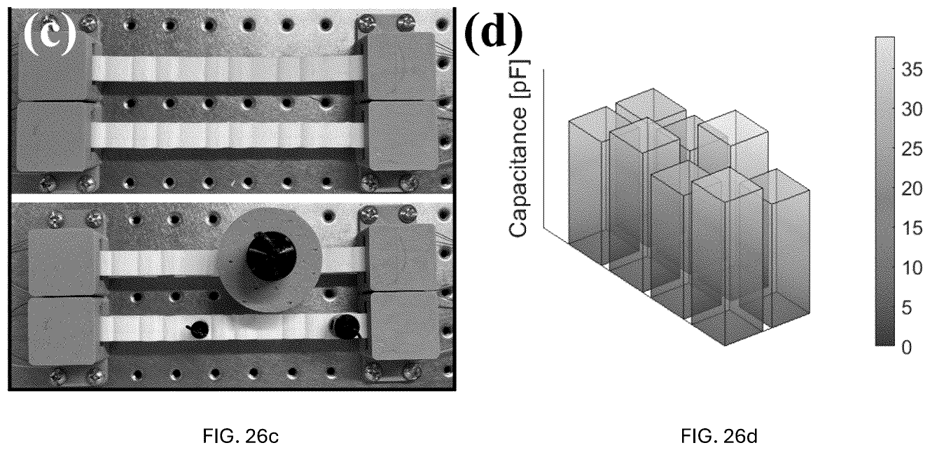

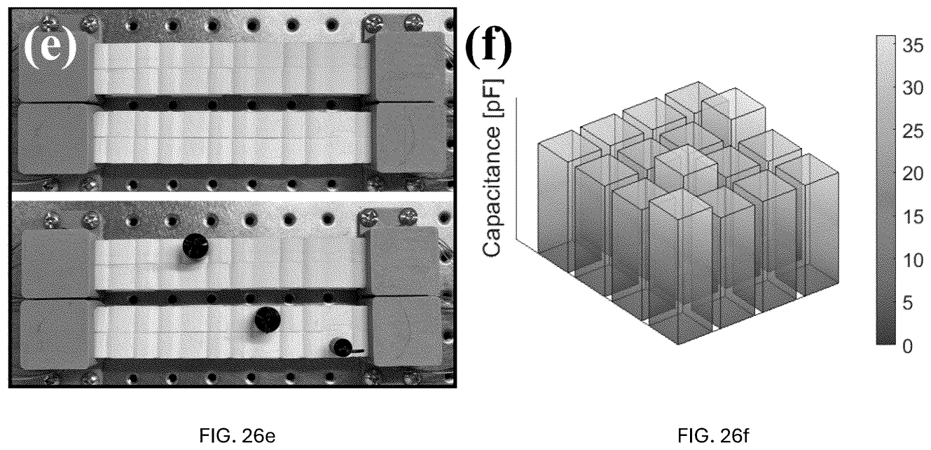

The fabricated stretchable electrospinning PVdF-based transducer has both piezoelectric sensing and capacitive sensing mechanisms. The first demonstration is about the application of the sensor to build a stretchable capacitive 4×4 sensing matrix. The electrospinning piezoelectrically active PVdF-TPU microfiber membrane with DIW printed electrodes' patterns is shown in FIG. 26a. FDM 3D printing was applied to printing soft stretchable 3D architectures using TPU filament (Shore hardness 60 A). Each 3D printed TPU part integrated with four individual sensors is considered as a sensing element. To build a 4×4 sensing matrix, four sensing elements needed. First, two sensing elements were used to build a 2×4 sensing matrix. The spatial location of these two sensing elements does not have to be in parallel as shown in FIG. 26c, which shows the top view of a 2×4 sensing matrix. The spatial location of these sensing elements including their stretching ratios can have a number of combinations. Two sensing elements can be: (1) installed in parallel or in perpendicular with each other or take any arbitrary angle, (2) installed at different vertical levels, (3) stretched for different ratios from 0% to 30%. It is critical that the calibration curve for the sensor stays unchanged regardless of the stretching ratio, because the designed structure provides the sensor the capability to be stretching insensitive sensor.

The calibration curves of each sensor should be determined before the test. During the test, three weights were placed on three sensors, respectively shown in FIG. 26c. The applied forces were regarded as static forces, which were different from the dynamic forces applied to test the piezoelectric output as provided herein. The capacitance of every one of the eight sensors was measured from the sensors by using an LCR meter at a constant frequency of 1 kHz to determine the forces applied based on the calibration curves of each sensor. The capacitance measurement results are visualized in FIG. 26d.

In the second test, the number of sensors in the sensing matrix was expanded to include sixteen sensors formed into a 4×4 sensing matrix. The top view of the sensing matrix is shown in FIG. 26e. Following the same test procedures, three weights were placed on three sensors in the sensing matrix. The capacitance of these sensors was measured individually with the aid of an LCR meter. The results are shown in FIG. 26f. The measured capacitance was compared with the calibration curves to determine the magnitude of the applied forces.

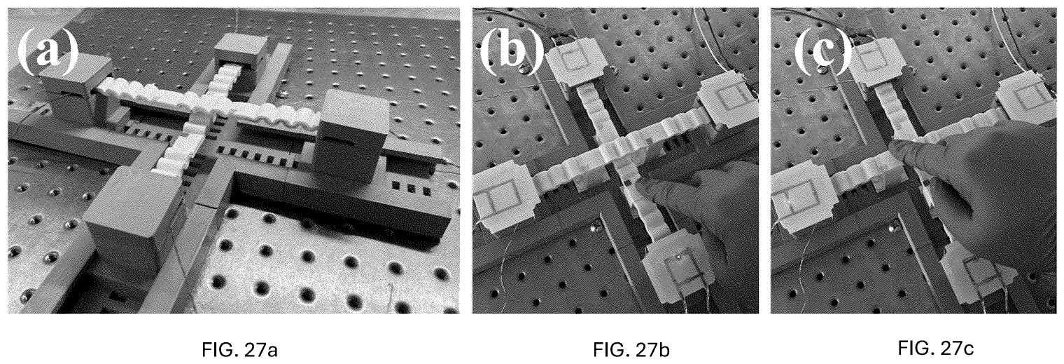

The application of the fabricated stretchable transducer is now provided. There are two individual sensors integrated into one sensing element. Two sensing elements were used with their spatial location specified in FIGS. 27a, 27b, and 27c which are photographs of a testing rig for testing stretchable 2×2 piezoelectric pressure sensing matrix fixed on a fully FDM 3D printed biaxial linear stretcher (FIG. 27a), where the fabricated 2×2 sensing matrix was integrated with light emitting diodes (LEDs) to visualize the piezoelectric output signals generated by sensors in the matrix; applying force (FIG. 27b); and releasing force (FIG. 27c). A fully 3D printed biaxial stretcher was used to stretch and fix the sensing matrix. The two sensing elements were fixed perpendicular to each other at different vertical levels. As explained above, the spatial location of the sensing elements is flexible. By using the 3D printed structure shown, the stretching ratio of these two sensing elements can be adjusted freely.

The sensing results were visualized by LEDs. Each sensor was connected with one individual charge amplifier circuit and the circuit output was connected with two LEDs with reversed polarity. Based on the piezoelectric output characteristics, applying a force can cause the corresponding sensor to generate a positive voltage spike which can turn on the red LED shown in FIG. 27b. The releasing of the applied force can lead to the generation of a negative voltage spike which can turn on the yellow LED shown in FIG. 27c. Therefore, the generated piezoelectric output corresponding to forces applying and releasing were visualized by the designed piezoelectric stretchable sensing matrix.

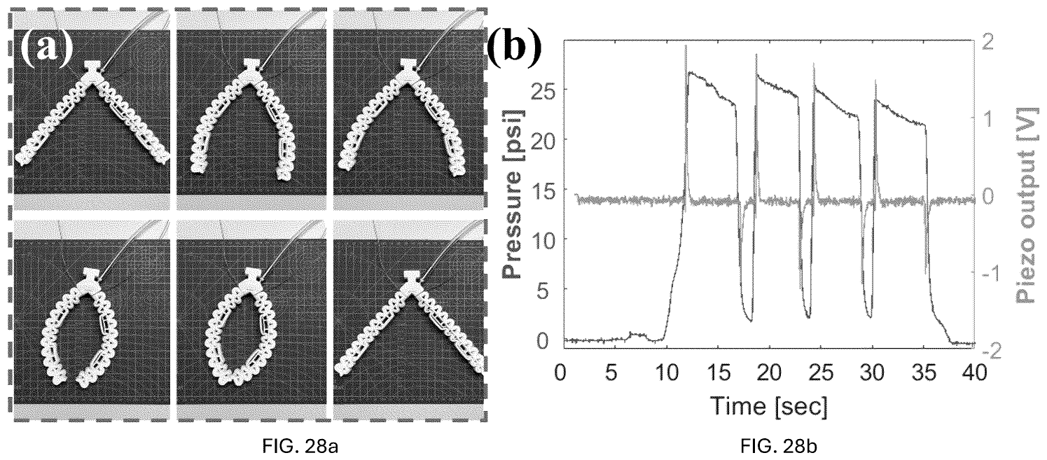

Integration of the transducer of the present disclosure with a soft gripper, e.g., in a robotic application is now discussed. The stretchable transducers of the present disclosure were integrated with a fully 3D printed soft gripper to measure the contact forces between the soft gripper and a rigid object. The grasping movement of the soft gripper is driven by the inflation of air. The increasing air pressure can cause the bending of the gripper. With the different extensions between the outer side and inner side of the soft gripper can cause the soft structure to bend towards inside to implement the grasping movement. A typical grasping movement which was recorded at different moments are shown in FIG. 28a which is photograph of the grasping function of an FDM 3D printed soft gripper driven by air pressure integrated with electrospinning PVdF/TPU microfiber-based piezoelectric pressure sensors.

When the soft gripper was used to grasp a rigid object, the piezoelectric output was recorded and plotted in the same plot with the air pressure inside the soft gripper as shown in FIG. 28b which is a graph of pressure in pounds per square inches vs. time while also showing the piezoelectric output in V. The air pressure increased gradually which corresponded to the bending movement of the “fingers”. When the air pressure started to increase, the soft actuator started to extend and bend towards the inner side to approach the object. The piezoelectric output voltage started to increase when the soft actuator contacted the object. The grasping movement was detected by the integrated piezoelectric pressure sensors to generate a positive spike. As the air pressure decreased led to the releasing movement of the soft gripper. From FIG. 28b, a negative spike was generated by the piezoelectric pressure sensor when the air pressure decreased to a specific value, which corresponded to the detachment of the object and the soft gripper. The measurement results about the variations of the air pressure inside the soft gripper and the piezoelectric output are consistent with the actual movement of the soft gripper. The designed demonstration proves the capability and reliability of using the stretchable piezoelectric pressure sensors to measure the pressure when a soft gripper was applied to perform a grasping task. The piezoelectric output signals are useful feedback to the control system to regulate the movement of the soft gripper to either increase the grasping force or reduce the force to implement a safe interaction with the objects in the unstructured environment.

Those having ordinary skill in the art will recognize that numerous modifications can be made to the specific implementations described above. The implementations should not be limited to the particular limitations described. Other implementations may be possible.

1. A stretchable transducer, comprising:
one or more rectangular sensing regions, each sensing region including
one or more sensing layers including
fibrous sensing materials,
the fibrous materials sandwiched between a top and a bottom electrode,
two or more substrates adapted to sandwich the one or more sensing layers
within said one or more sensing regions,
said two or more substrates form one or more serpentine regions adapted to allow stretchability of the stretchable transducer, wherein the two or more substrates extend longitudinally in between the one or more sensing regions and outward from the one or more sensing regions thus forming the one or more serpentine regions and further outward to one or more electrical connection regions and yet further outward to two clamping regions, the two or more substrates having axial gaps therebetween, thus forming the one or more serpentine regions and thus allowing insertion of the one or more sensing regions in said gaps;
said one or more electrical connection regions distally extended longitudinally from the one or more serpentine regions, wherein the one or more electrodes extend longitudinally from the one or more sensing regions through said gaps formed in said serpentine regions and terminating at said one or more electrical connection regions;
said two clamping regions distally extended longitudinally from the one or more electrical connection regions adapted to provide coupling to the stretchable transducer; and
an encasing layer adapted to encase said one or more sensing regions, said one or more sensing regions, said one or more electrical connection regions, and said two clamping regions.

2. The stretchable transducer of claim 1, wherein the one or more fibrous sensing materials is made of Polyvinylidene fluoride or polyvinylidene difluoride (PVdF) and thermoplastic polyurethane (TPU).

3. The stretchable transducer of claim 1, wherein the two or more substrates are made of thermoplastic polyurethane (TPU).

4. The stretchable transducer of claim 1, wherein the one or more fibrous sensing materials is made by a gap electrospinning process.

5. The stretchable transducer of claim 1, wherein the one or more top and bottom electrodes are made by a direct ink writing (DIW) process.

6. The stretchable transducer of claim 1, wherein the one or more top and bottom electrodes are made of silver.

7. The stretchable transducer of claim 5, wherein the one or more top and bottom electrodes are made of silver ink.

8. The stretchable transducer of claim 1, wherein if the one or more sensing layers is two sensing layers, the two sets of top and bottom electrodes are coupled to each other in a series manner.

9. The stretchable transducer of claim 1, wherein if the one or more sensing layers is two sensing layers, the two sets of top and bottom electrodes are coupled to each other in a parallel manner.

10. The stretchable transducer of claim 1, wherein the encasing layer is made of a polymer including Polydimethylsiloxane (PDMS).

11. A stretchable transducing system, comprising:
a stretchable transducer;
an electrical circuit configured to i) receive an electrical signal from the stretchable transducer in a sensing mode corresponding to changes in environment, or ii) provide an electrical signal to the stretchable transducer in an actuator mode to thereby cause changes in the environment;
wherein the stretchable transducer includes:
one or more rectangular sensing regions, each sensing region including
one or more sensing layers including
fibrous sensing materials,
the fibrous materials sandwiched between a top and a bottom electrode,
two or more substrates adapted to sandwich the one or more
sensing layers within said one or more sensing regions,
said two or more substrates form one or more serpentine regions adapted to allow stretchability of the stretchable transducer, wherein the two or more substrates extend longitudinally in between the one or more sensing regions and outward from the one or more sensing regions thus forming the one or more serpentine regions and further outward to one or more electrical connection regions and yet further outward to two clamping regions, the two or more substrates having axial gaps therebetween, thus forming the one or more serpentine regions and thus allowing insertion of the one or more sensing regions in said gaps;
said one or more electrical connection regions distally extended longitudinally from the one or more serpentine regions, wherein the one or more electrodes extend longitudinally from the one or more sensing regions through said gaps formed in said serpentine regions and terminating at said one or more electrical connection regions;
said two clamping regions distally extended longitudinally from the one or more electrical connection regions adapted to provide coupling to the stretchable transducer; and
an encasing layer adapted to encase said one or more sensing regions, said one or more sensing regions, said one or more electrical connection regions, and said two clamping regions.

12. The stretchable transducing system of claim 11, wherein the one or more fibrous sensing materials is made of Polyvinylidene fluoride or polyvinylidene difluoride (PVdF) and thermoplastic polyurethane (TPU).

13. The stretchable transducing system of claim 11, wherein the two or more substrates are made of thermoplastic polyurethane (TPU).

14. The stretchable transducing system of claim 11, wherein the one or more fibrous sensing materials is made by a gap electrospinning process.

15. The stretchable transducing system of claim 11, wherein the one or more top and bottom electrodes are made by a direct ink writing (DIW) process.

16. The stretchable transducing system of claim 11, wherein the one or more top and bottom electrodes are made of silver.

17. The stretchable transducing system of claim 15, wherein the one or more top and bottom electrodes are made of silver ink.

18. The stretchable transducing system of claim 11, wherein if the one or more sensing layers is two sensing layers, the two sets of top and bottom electrodes are coupled to each other in a series manner.

19. The stretchable transducing system of claim 11, wherein if the one or more sensing layers is two sensing layers, the two sets of top and bottom electrodes are coupled to each other in a parallel manner.

20. The stretchable transducing system of claim 11, wherein the encasing layer is made of a polymer including Polydimethylsiloxane (PDMS).
